(19) United States
(12) Patent Application Publication
(10) Pub. No.: US 2022/0326566 A1
(43) Pub. Date: Oct. 13, 2022

(54) COLOR FILTER, METHOD FOR MANUFACTURING COLOR FILTER, SOLID-STATE IMAGING ELEMENT, AND DISPLAY DEVICE

(71) Applicant: FUJIFILM Corporation, Tokyo (JP)

(72) Inventors: Hiroaki OGAWA, Haibara-gun (JP); Keiji YAMAMOTO, Haibara-gun (JP); Daisuke KASHIWAGI, Haibara-gun (JP)

(73) Assignee: FUJIFILM Corporation, Tokyo (JP)

(21) Appl. No.: 17/847,506

(22) Filed: Jun. 23, 2022

Related U.S. Application Data
(63) Continuation of application No. PCT/JP2020/046846, filed on Dec. 16, 2020.

(30) Foreign Application Priority Data
Dec. 25, 2019 (JP) 2019-233638

(51) Int. Cl. G02F 1/1335

(52) U.S. Cl. CPC G02F 1/133516

(57) ABSTRACT

Provided are a color filter including a green pixel and a red pixel, in which the green pixel includes Color Index Pigment Green 7 and Color Index Pigment Yellow 150, and the red pixel includes one or more red colorants selected from Color Index Pigment Red 177, Color Index Pigment Red 264, and Color Index Pigment Red 269, and a yellow colorant other than Color Index Pigment Yellow 150; a method for manufacturing a color filter; a solid-state imaging element; and a display device.

### CROSS-REFERENCE TO RELATED APPLICATIONS

This application is a Continuation of PCT International Application No. PCT/JP2020/046846 filed on Dec. 16, 2020, which claims priority under 35 U.S.C. § 119(a) to Japanese Patent Application No. 2019-233638 filed on Dec. 25, 2019. Each of the above application(s) is hereby expressly incorporated by reference, in its entirety, into the present application.

### BACKGROUND OF THE INVENTION

### 1. Field of the Invention

The present invention relates to a color filter, a method for manufacturing a color filter, a solid-state imaging element, and a display device.

### 2. Description of the Related Art

In various display devices, a color filter having a plurality of colored pixels is used for colorizing a display image. For example, JP2002-258267A discloses a color filter including a red colored pixel, a green colored pixel, and a blue colored pixel.

### SUMMARY OF THE INVENTION

An equipment equipped with the color filter may also be used in high temperature environments. Therefore, in the color filter, it is desired that color mixing due to color transfer between pixels of other colors is small even in a case of being exposed to a high temperature.

Accordingly, an object of the present invention is to provide a color filter in which color mixing due to color transfer between pixels of other colors is suppressed even in a case of being exposed to a high temperature, a method for manufacturing a color filter, a solid-state imaging element, and a display device.

As a result of intensive studies on a color filter having a green pixel and a red pixel, the present inventor has found that the above-described object can be achieved by using a color filter which includes, as a green pixel, a green pixel including Color Index Pigment Green 7 and Color Index Pigment Yellow 150, and includes, as a red pixel, one or more red colorants selected from Color Index Pigment Red 177, Color Index Pigment Red 264, and Color Index Pigment Red 269, and a yellow colorant other than Color Index Pigment Yellow 150, and has completed the present invention. Therefore, the present invention provides the following.

<1> A color filter comprising:

a green pixel; and

a red pixel,

in which the green pixel includes Color Index Pigment Green 7 and Color Index Pigment Yellow 150, and

the red pixel includes one or more red colorants selected from Color Index Pigment Red 177, Color Index Pigment Red 264, and Color Index Pigment Red 269, and a yellow colorant other than Color Index Pigment Yellow 150.

<2> The color filter according to <1>,

in which a side surface of the green pixel and a side surface of the red pixel are in contact with each other.

<3> The color filter according to <1> or <2>,

in which the yellow colorant other than Color Index Pigment Yellow 150, which is included in the red pixel, is at least one selected from an isoindoline compound or a quinophthalone compound.

<4> The color filter according to <1> or <2>,

in which the yellow colorant other than Color Index Pigment Yellow 150, which is included in the red pixel, is at least one selected from Color Index Pigment Yellow 139 or Color Index Pigment Yellow 185.

<5> The color filter according to any one of <1> to <4>,

in which the green pixel includes 50 to 240 parts by mass of Color Index Pigment Yellow 150 with respect to 100 parts by mass of Color Index Pigment Green 7.

<6> The color filter according to any one of <1> to <5>,

in which the red pixel includes 5 to 100 parts by mass of the yellow colorant other than Color Index Pigment Yellow 150 with respect to 100 parts by mass of the one or more red colorants selected from Color Index Pigment Red 177, Color Index Pigment Red 264, and Color Index Pigment Red 269.

<7> The color filter according to any one of <1> to <6>, in which, in light having a wavelength range of 400 to 700 nm, a difference between a wavelength of light on a short wavelength side where a transmittance of the green pixel is 5% and a wavelength of light on a long wavelength side where a transmittance of the red pixel is 5% is 98 to 115 nm.

<8> The color filter according to any one of <1> to <7>,

in which, in light having a wavelength range of 400 to 700 nm, a difference between a wavelength of light on a long wavelength side where a transmittance of the green pixel is 30% and a wavelength of light on a long wavelength side where a transmittance of the red pixel is 30% is 10 to 33 nm.

<9> The color filter according to any one of <1> to <8>, further comprising:

a blue pixel.

<10> A method for manufacturing the color filter according to any one of <1> to <9>, the method comprising:

a step of forming a green pixel using a composition for a green pixel, which includes Color Index Pigment Green 7 and Color Index Pigment Yellow 150; and

a step of forming a red pixel using a composition for a red pixel, which includes one or more red colorants selected from Color Index Pigment Red 177, Color Index Pigment Red 264, and Color Index Pigment Red 269, and a yellow colorant other than Color Index Pigment Yellow 150.

<11> The method of manufacturing the color filter according to <10>,

in which, in the step of forming a green pixel, the green pixel is formed by a photolithography method using the composition for a green pixel, and

in the step of forming a red pixel, the red pixel is formed by a photolithography method using the composition for a red pixel.

<12> The method for manufacturing the color filter according to <10> or <11>,

in which at least one selected from the composition for a green pixel or the composition for a red pixel includes an alkali-soluble resin.

<13> The method for manufacturing the color filter according to any one of <10> to <12>,

in which at least one selected from the composition for a green pixel or the composition for a red pixel includes a resin which has a repeating unit including a blocked isocyanate group.

<14> The method for manufacturing the color filter according to any one of <10> to <13>,

in which the step of forming a green pixel and the step of forming a red pixel are each performed at a temperature of 150° C. or lower.

<15> A solid-state imaging element comprising:

the color filter according to any one of <1> to <9>.

<16> A display device comprising:

the color filter according to any one of <1> to <9>.

According to the present invention, it is possible to provide a color filter in which color mixing due to color transfer between pixels of other colors is suppressed even in a case of being exposed to a high temperature, a method for manufacturing a color filter, a solid-state imaging element, and a display device.

### BRIEF DESCRIPTION OF THE DRAWINGS

FIG. 1 is a diagram showing an embodiment in which a side surface of a green pixel and a side surface of a red pixel are in contact with each other.

FIG. 2 is a diagram showing another embodiment in which a side surface of a green pixel and a side surface of a red pixel are in contact with each other.

### DESCRIPTION OF THE PREFERRED EMBODIMENTS

Hereinafter, the details of the present invention will be described.

In the present specification, unless specified as a substituted group or as an unsubstituted group, a group (atomic group) denotes not only a group (atomic group) having no substituent but also a group (atomic group) having a substituent. For example, an “alkyl group” includes not only an alkyl group having no substituent (unsubstituted alkyl group), but also an alkyl group having a substituent (substituted alkyl group).

In the present specification, unless specified otherwise, “exposure” denotes not only exposure using light but also drawing using a corpuscular beam such as an electron beam or an ion beam. In addition, generally, examples of the light used for exposure include an actinic ray or radiation, for example, a bright light spectrum of a mercury lamp, a far ultraviolet ray represented by excimer laser, an extreme ultraviolet ray (EUV light), an X-ray, or an electron beam.

In the present specification, a numerical range represented by “to” means a range including numerical values before and after “to” as a lower limit value and an upper limit value.

In the present specification, a total solid content denotes the total mass of all the components of the composition excluding a solvent.

In the present specification, “(meth)acrylate” represents either or both of acrylate and methacrylate, “(meth)acryl” represents either or both of acryl and methacryl, “(meth)allyl” represents either or both of allyl and methallyl, and “(meth)acryloyl” represents either or both of acryloyl and methacryloyl.

In the present specification, the term “step” is not only an independent step, but also includes a step which is not clearly distinguished from other steps in a case where an intended action of the step is obtained.

In the present specification, a weight-average molecular weight (Mw) and a number-average molecular weight (Mn) are each defined as a value in terms of polystyrene through measurement by means of gel permeation chromatography (GPC).

<Color Filter>

A color filter according to an embodiment of the present invention is a color filter including a green pixel and a red pixel, in which the green pixel includes Color Index Pigment Green 7 and Color Index Pigment Yellow 150, and the red pixel includes one or more red colorants selected from Color Index Pigment Red 177, Color Index Pigment Red 264, and Color Index Pigment Red 269, and a yellow colorant other than Color Index Pigment Yellow 150.

In the color filter according to the embodiment of the present invention, even in a case of being exposed to a high temperature, it is possible to suppress color mixing due to color transfer between the green pixel and the red pixel. The detailed reason why this effect can be obtained is not clear, but is presumed that, since the green pixel and the red pixel are each composed of the above-described colorant, a movement of colorant between the green pixel and the red pixel can be suppressed, or precipitation due to aggregation of the colorant included in the green pixel and the colorant included in the red pixel near an interface between the pixels can be suppressed.

In addition, since the color filter according to the embodiment of the present invention is composed of the green pixel and the red pixel each including the above-described colorant, color separation between the green pixel and the red pixel is also excellent.

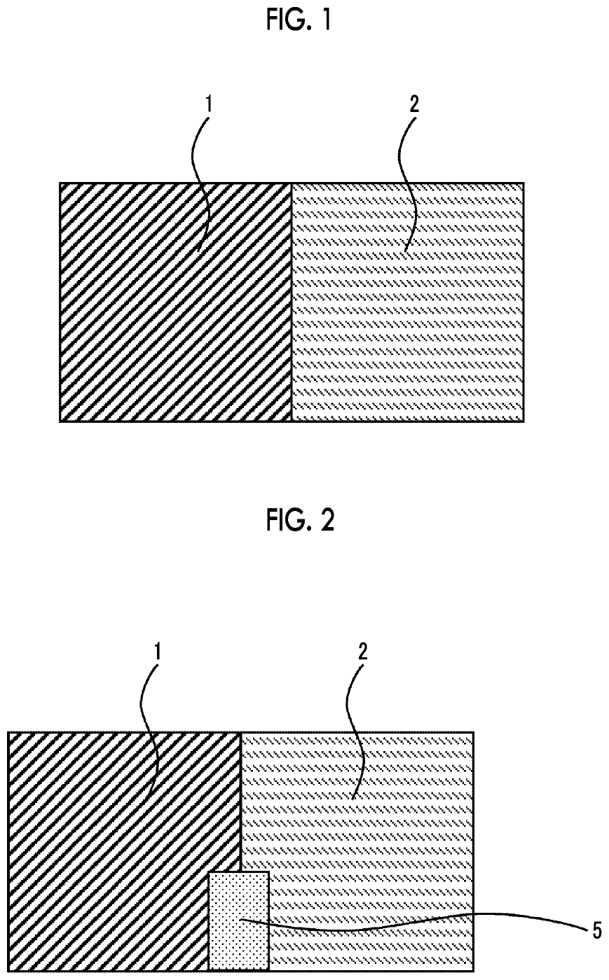

In the color filter according to the embodiment of the present invention, the effect of the present invention is remarkably exhibited in a case where a side surface of the green pixel and a side surface of the red pixel are in contact with each other. Here, examples of the case where the side surface of the green pixel and the side surface of the red pixel are in contact with each other include an aspect in which, as shown in FIG. 1, the side surfaces of both are in direct contact with each other without the presence of another layer such as a partition wall at an interface between a green pixel 1 and a red pixel 2, and an aspect in which, as shown in FIG. 2, a partition wall 5 lower than these pixels is provided between the green pixel 1 and the red pixel 2, and the side surfaces of both are in contact with each other at an upper portion of the partition wall 5. In FIGS. 1 and 2, thicknesses of the green pixel and the red pixel are described to be the same, but the thicknesses of the two may be different from each other.

In the color filter according to the embodiment of the present invention, from the viewpoint of color separation, in light having a wavelength range of 400 to 700 nm, a difference between a wavelength of light on a short wavelength side where a transmittance of the green pixel is 5% and a wavelength of light on a long wavelength side where a transmittance of the red pixel is 5% is preferably 98 to 115 nm, more preferably 100 to 115 nm, and still more preferably 105 to 115 nm.

In addition, in the color filter according to the embodiment of the present invention, from the viewpoint of color separation, in light having a wavelength range of 400 to 700 nm, a difference between a wavelength of light on a long wavelength side where a transmittance of the green pixel is 30% and a wavelength of light on a long wavelength side where a transmittance of the red pixel is 30% is preferably 10 to 33 nm, more preferably 18 to 33 nm, and still more preferably 25 to 33 nm.

(Green Pixel)

First, the green pixel will be described in detail. The green pixel includes Color Index (C. I.) Pigment Green 7 and C. I. Pigment Yellow 150. It is preferable that the green pixel includes 50 to 240 parts by mass of C. I. Pigment Yellow 150 with respect to 100 parts by mass of C. I. Pigment Green 7. The upper limit is preferably 200 parts by mass or less and more preferably 150 parts by mass or less. The lower limit is preferably 80 parts by mass or more and more preferably 100 parts by mass or more.

The green pixel may further contain a green colorant other than C. I. Pigment Green 7. Examples of other green colorants include C. I. Pigment Green 10, 36, 37, 58, 59, 62, 63, 64, 65, and 66. In addition, examples of the above-described green colorant include a halogenated zinc phthalocyanine pigment having an average number of halogen atoms in one molecule of 10 to 14, an average number of bromine atoms in one molecule of 8 to 12, and an average number of chlorine atoms in one molecule of 2 to 5. Specific examples thereof include the compounds described in WO2015/118720A. In addition, examples of the above-described green colorant include a compound described in CN2010-6909027A, a phthalocyanine compound described in WO2012/102395A, which has phosphoric acid ester as a ligand, a phthalocyanine compound described in JP2019-008014A, a phthalocyanine compound described in JP2018-180023A, and a compound described in JP2019-038958A.

Examples of a preferred aspect of the green colorant included in the green pixel include the following aspects G1 and G2, and from the viewpoint of color separation, the following aspect G1 is preferable.

Aspect G1: aspect in which the green colorant is substantially only C. I. Pigment Green 7

Aspect G2: aspect in which the green colorant includes C. I. Pigment Green 7 and includes, as a green colorant other than C. I. Pigment Green 7, at least one selected from C. I. Pigment Green 36 or C. I. Pigment Green 58

The case where the green colorant is substantially only C. I. Pigment Green 7 means that a content of C. I. Pigment Green 7 in the green colorant is 99.5 mass % or more, preferably 99.9 mass % or more.

In the above-described green colorant of the aspect G2, as the green colorant other than C. I. Pigment Green 7, from the viewpoint of fastness and stability, C. I. Pigment Green 36 is preferable. In addition, in the above-described green colorant of the aspect G2, a content of the green colorant other than C. I. Pigment Green 7 is preferably 0.1 to 100 parts by mass, more preferably 1 to 50 parts by mass, and still more preferably 5 to 25 parts by mass with respect to 100 parts by mass of C. I. Pigment Green 7. In addition, a content of C. I. Pigment Green 36 is preferably 0.1 to 100 parts by mass, more preferably 1 to 50 parts by mass, and still more preferably 5 to 25 parts by mass with respect to 100 parts by mass of C. I. Pigment Green 7.

The green pixel can contain a yellow colorant other than C. I. Pigment Yellow 150. Examples of the yellow colorant other than C. I. Pigment Yellow 150 include a yellow colorant 1 described later, and from the viewpoint of color separation and light resistance, C. I. Pigment Yellow 129, 138, 139, or 185 is preferable.

Examples of a preferred aspect of the yellow colorant included in the green pixel include the following aspects Y1 and Y2, and from the viewpoint of light resistance, the following aspect Y1 is preferable.

Aspect Y1: aspect in which the yellow colorant is substantially only C. I. Pigment Yellow 150

Aspect Y2: aspect in which the yellow colorant includes C. I. Pigment Yellow 150 and a yellow colorant other than C. I. Pigment Yellow 150

In the present specification, the case where the yellow colorant is substantially only C. I. Pigment Yellow 150 means that a content of C. I. Pigment Yellow 150 in the yellow colorant is 99.5 mass % or more, preferably 99.9 mass % or more.

In addition, in the above-described yellow colorant of the aspect Y2, a content of the yellow colorant other than C. I. Pigment Yellow 150 is preferably 0.1 to 100 parts by mass, more preferably 1 to 50 parts by mass, and still more preferably 10 to 25 parts by mass with respect to 100 parts by mass of C. I. Pigment Yellow 150.

It is preferable that the green pixel contains 50 to 240 parts by mass of the yellow colorant with respect to 100 parts by mass of the green colorant. The upper limit is preferably 200 parts by mass or less and more preferably 150 parts by mass or less. The lower limit is preferably 80 parts by mass or more and more preferably 100 parts by mass or more.

In addition, a total content of the green colorant and the yellow colorant in the total amount of colorants included in the green pixel is preferably 50 to 100 mass %, more preferably 75 to 100 mass %, and still more preferably 90 to 100 mass %.

In addition, a total content of C. I. Pigment Green 7 and C. I. Pigment Yellow 150 in the total amount of colorants included in the green pixel is preferably 50 to 100 mass %, more preferably 75 to 100 mass %, and still more preferably 90 to 100 mass %.

In addition, the green pixel contains C. I. Pigment Green 7 and C. I. Pigment Yellow 150 in a total amount of preferably 15 to 55 mass %, more preferably 22 to 50 mass %, and still more preferably 29 to 45 mass %.

The green pixel may contain a colorant (hereinafter, also referred to as other colorants) other than the green colorant and the yellow colorant, but from the viewpoint of color separation, it is particularly preferable that the green pixel does not substantially contain the other colorants. Examples of the other colorants include chromatic colorants such as a red colorant, a blue colorant, a violet colorant, and an orange colorant. The case where the green pixel does not substantially contain the other colorants means that a content of the other colorants in colorants included in the green pixel is less than 0.5 mass %, preferably less than 0.1 mass % and more preferably 0 mass %.

With regard to the green pixel, the maximum value of a transmittance to light having a wavelength of 495 nm or more and less than 550 nm is preferably 60% or more, more preferably 65% or more, and still more preferably 70% or more.

In addition, an average transmittance to light having a wavelength of 495 nm or more and less than 550 nm is preferably 45% or more, more preferably 50% or more, and still more preferably 55% or more.

In addition, a transmittance to light having a wavelength of 450 nm is preferably 10% or less, more preferably 5% or less, and still more preferably 2% or less.

In addition, an average transmittance to light having a wavelength of 400 nm or more and 450 nm or less is preferably 10% or less, more preferably 5% or less, and still more preferably 1% or less.

In addition, an average transmittance to light having a wavelength of 550 nm or more and 600 nm or less is preferably 60% or less, more preferably 50% or less, and still more preferably 40% or less.

A thickness of the green pixel is preferably 0.5 to 3.0 The lower limit is preferably 0.8 μm or more, more preferably 1.0 μm or more, and still more preferably 1.1 μm or more. The upper limit is preferably 2.5 μm or less, more preferably 2.0 μm or less, and still more preferably 1.8 μm or less.

In addition, a line width (pattern size) of the green pixel is preferably 2.0 to 10.0 μm. The upper limit is preferably 7.5 μm or less, more preferably 5.0 μm or less, and still more preferably 4.0 μm or less. The lower limit is preferably 2.25 μm or more, more preferably 2.5 μm or more, and still more preferably 2.75 μm or more.

The green pixel can be formed using a composition for a green pixel, which includes C. I. Pigment Green 7 and C. I. Pigment Yellow 150. The composition for a green pixel will be described later.

(Red pixel)

Next, the red pixel will be described in detail. The red pixel includes one or more red colorants selected from C. I. Pigment Red 177, C. I. Pigment Red 264, and C. I. Pigment Red 269, and a yellow colorant other than C. I. Pigment Yellow 150.

Examples of the yellow colorant other than C. I. Pigment Yellow 150 (hereinafter, also referred to as a yellow colorant 1) include C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232 (methine-based), 233 (quinoline-based), 234 (aminoketone-based), 235 (aminoketone-based), and 236 (aminoketone-based).

In addition, as the yellow colorant 1, compounds described in JP2017-201003A, compounds described in JP2017-197719A, compounds described in paragraph Nos. 0011 to 0062 and 0137 to 0276 of JP2017-171912A, compounds described in paragraph Nos. 0010 to 0062 and 0138 to 0295 of JP2017-171913A, compounds described in paragraph Nos. 0011 to 0062 and 0139 to 0190 of JP2017-171914A, compounds described in paragraph Nos. 0010 to 0065 and 0142 to 0222 of JP2017-171915A, quinophthalone compounds described in paragraph Nos. 0011 to 0034 of JP2013-054339A, quinophthalone compounds described in paragraph Nos. 0013 to 0058 of JP2014-026228A, isoindoline compounds described JP2018-062644A, quinophthalone compounds described in JP2018-203798A, quinophthalone compounds described in JP2018-062578A, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765A (JP-S48-032765A), quinophthalone compounds described in JP2019-008014A, quinophthalone compounds described in JP6607427B, methine dyes described in JP2019-073695A, methine dyes described in JP2019-073696A, methine dyes described in JP2019-073697A, methine dyes described in JP2019-073698A, a compound represented by Formula (QP1), and a compound represented by Formula (QP2) can also be used. In addition, from the viewpoint of improving color value, a multimerized compound of these compounds is also preferably used.

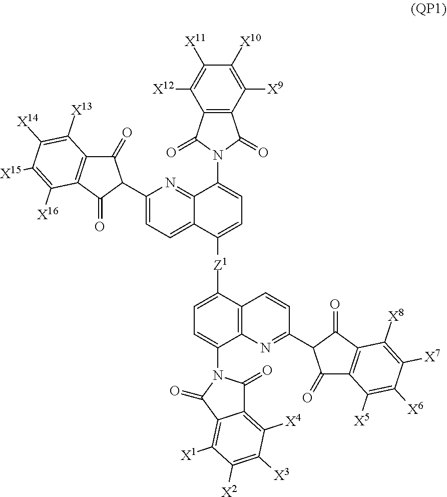

In Formula (QP1), X¹ to X¹⁶ each independently represent a hydrogen atom or a halogen atom, and Z¹ represents an alkylene group having 1 to 3 carbon atoms. Specific examples of the compound represented by Formula (QP1) include compounds described in paragraph No. 0016 of JP6443711B.

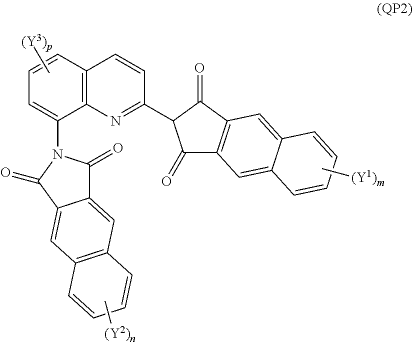

In Formula (QP2), Y¹ to Y³ each independently represent a halogen atom. n and m represent an integer of 0 to 6, and p represents an integer of 0 to 5. (n+m) is 1 or more. Specific examples of the compound represented by Formula (QP2) include compounds described in paragraph Nos. 0047 and 0048 of JP6432077B.

The above-described yellow colorant 1 is preferably at least one selected from an isoindoline compound or a quinophthalone compound, and more preferably at least one selected from C. I. Pigment Yellow 139 or C. I. Pigment Yellow 185. In addition, the above-described yellow colorant 1 is preferably a yellow colorant different from the yellow colorant included in the green pixel.

The yellow colorant included in the red pixel may contain C. I. Pigment Yellow 150, but from the viewpoint that it is easier to suppress color transfer between the green pixel and the red pixel, it is preferable that the yellow colorant does not substantially contain C. I. Pigment Yellow 150. That is, it is preferable that the yellow colorant included in the red pixel is substantially only the yellow colorant 1. In the present specification, the case where the yellow colorant does not substantially contain C. I. Pigment Yellow 150 means that a content of C. I. Pigment Yellow 150 in the yellow colorant is 0.5 mass % or less, preferably 0.1 mass % or less and particularly preferably 0 mass %.

The red pixel includes one or more red colorants (hereinafter, also referred to as a red colorant 1) selected from C. I. Pigment Red 177, C. I. Pigment Red 264, and C. I. Pigment Red 269. From the viewpoint of durability, the red colorant 1 is preferably C. I. Pigment Red 177 or 264.

The red pixel can contain a red colorant other than the above-described red colorant 1. Examples of other red colorants include C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 178, 179, 184, 185, 187, 188, 190, 200, 202, 206, 207, 208, 209, 210, 216, 220, 224, 226, 242, 246, 254, 255, 270, 272, 279, 291, 294 (xanthene-based, Organo Ultramarine, Bluish Red), 295 (monoazo-based), 296 (diazo-based), and 297 (aminoketone-based). In addition, as the other red colorants, diketopyrrolopyrrole compounds described in JP2017-201384A, in which the structure has at least one substituted bromine atom, diketopyrrolopyrrole compounds described in paragraph Nos. 0016 to 0022 of JP6248838B, diketopyrrolopyrrole compounds described in WO2012/102399A, diketopyrrolopyrrole compounds described in WO2012/117965A, naphtholazo compounds described in JP2012-229344, red colorants described in JP6516119B, red colorant described in JP6525101B, and the like can also be used. In addition, as the red colorant, a compound having a structure that an aromatic ring group in which a group bonded with an oxygen atom, a sulfur atom, or a nitrogen atom is introduced to an aromatic ring is bonded to a diketopyrrolopyrrole skeleton can be used.

A content of the above-described red colorant 1 in the red colorant included in the red pixel is preferably 50 to 100 mass %, more preferably 75 to 100 mass %, and still more preferably 90 to 100 mass %.

The red pixel preferably includes 5 to 100 parts by mass of the above-described yellow colorant 1, more preferably includes 10 to 90 parts by mass thereof, and still more preferably 20 to 80 parts by mass thereof with respect to 100 parts by mass of the above-described red colorant 1.

In the red pixel, a total content of the above-described red colorant 1 and the above-described yellow colorant 1 is preferably 15 to 60 mass %, more preferably 22 to 52 mass %, and still more preferably 29 to 45 mass %.

The red pixel may contain a colorant (hereinafter, also referred to as other colorants) other than the red colorant and the yellow colorant. Examples of the other colorants include a violet colorant and an orange colorant. Examples of the violet colorant include C. I. Pigment Violet 1, 19, 23, 27, 32, 37, 42, 60, and 61. Examples of the orange colorant include C. I. Pigment Orange 2, 5, 13, 16, 17:1, 31, 34, 36, 38, 43, 46, 48, 49, 51, 52, 55, 59, 60, 61, 62, 64, 71, and 73. A content of the other colorants is preferably 20 parts by mass or less, more preferably 12 parts by mass or less, and still more preferably 6 parts by mass or less with respect to 100 parts by mass of the total of the above-described red colorant 1 and the above-described yellow colorant 1.

With regard to the above-described red pixel, the maximum value of a transmittance to light having a wavelength of 400 to 550 nm is preferably 5% or less, more preferably 3% or less, and still more preferably 1% or less. In addition, an average transmittance to light having a wavelength of 400 to 550 nm is preferably 3% or less, more preferably 1% or less, and still more preferably 0.5% or less. In addition, the minimum value of a transmittance to light having a wavelength of 600 to 700 nm is preferably 10% or more, more preferably 25% or more, and still more preferably 40% or more. In addition, an average transmittance to light having a wavelength of 600 to 700 nm is preferably 80% or more, more preferably 90% or more, and still more preferably 95% or more.

A thickness of the red pixel is preferably 0.5 to 3.0 μm. The lower limit is preferably 0.8 μm or more, more preferably 1.0 μm or more, and still more preferably 1.1 μm or more. The upper limit is preferably 2.5 μm or less, more preferably 2.0 μm or less, and still more preferably 1.8 μm or less.

In addition, a line width (pattern size) of the red pixel is preferably 2.0 to 10.0 μm. The upper limit is preferably 7.5 μm or less, more preferably 5.0 μm or less, and still more preferably 4.0 μm or less. The lower limit is preferably 2.25 μm or more, more preferably 2.5 μm or more, and still more preferably 2.75 μm or more.

The red pixel can be formed using a composition for a red pixel, which includes one or more red colorants selected from Color Index Pigment Red 177, Color Index Pigment Red 264, and Color Index Pigment Red 269, and a yellow colorant other than Color Index Pigment Yellow 150. The composition for a red pixel will be described later.

(Other Pixels)

The color filter according to the embodiment of the present invention can have a pixel other than the green pixel and the red pixel. Examples of other pixels include a blue pixel, a yellow pixel, a magenta pixel, a cyan pixel, a pixel of infrared transmitting filter, and a transparent pixel, and a blue pixel is preferable.

The blue pixel preferably includes a blue colorant. A content of the blue colorant in colorants included in the blue pixel is preferably 40 mass % or more and more preferably 60 mass % or more. In addition, the blue pixel preferably includes 20 mass % or more of the blue colorant, more preferably includes 25 mass % or more thereof, and still more preferably includes 30 mass % or more thereof. The upper limit of the content of the blue colorant is preferably 80 mass % or less, more preferably 70 mass % or less, and still more preferably 60 mass % or less. Examples of the blue colorant include blue pigments such as C. I. Pigment Blue 1, 2, 15, 15:1, 15:2, 15:3, 15:4, 15:6, 16, 22, 29, 60, 64, 66, 79, 80, 87 (monoazo-based), and 88 (methine-based), and C. I. Pigment Blue 15:6 is preferable.

It is more preferable that the above-described blue pixel further includes at least one selected from a violet colorant or a red colorant, in addition to the blue colorant. A content of the violet colorant is preferably 10 to 90 parts by mass, more preferably 20 to 75 parts by mass, and still more preferably 30 to 60 parts by mass with respect to 100 parts by mass of the blue colorant. Examples of the violet colorant and the red colorant include violet pigments such as C. I. Pigment Violet 1, 19, 23, 27, 32, 37, 42, 60 (triarylmethane-based), and 61 (xanthene-based), and xanthene compounds. Examples of the xanthene compound include salt-forming compounds obtained by reacting a resin having a cationic group in the side chain with a xanthene-based acid dye, which are described in paragraph Nos. 0025 to 0077 of JP2016-180834A.

With regard to the blue pixel, the maximum value of a transmittance to light having a wavelength of 400 to 500 nm is preferably 50% or more, more preferably 60% or more, and still more preferably 70% or more. In addition, an average transmittance to light having a wavelength of 400 to 500 nm is preferably 40% or more, more preferably 50% or more, and still more preferably 60% or more. In addition, the minimum value of a transmittance to light having a wavelength of 550 to 700 nm is preferably 30% or less, more preferably 20% or less, and still more preferably 10% or less. In addition, an average transmittance to light having a wavelength of 550 to 700 nm is preferably 25% or less, more preferably 10% or less, and still more preferably 5% or less.

A thickness of the blue pixel is preferably 0.5 to 3.0 μm. The lower limit is preferably 0.8 μm or more, more preferably 1.0 μm or more, and still more preferably 1.1 μm or more. The upper limit is preferably 2.5 μm or less, more preferably 2.0 μm or less, and still more preferably 1.8 μm or less.

In addition, a line width (pattern size) of the blue pixel is preferably 2.0 to 10.0 μm. The upper limit is preferably 7.5 μm or less, more preferably 5.0 μm or less, and still more preferably 4.0 μm or less. The lower limit is preferably 2.25 μm or more, more preferably 2.5 μm or more, and still more preferably 2.75 μm or more.

<Composition for Green Pixel>

<<Colorant>>

The composition for a green pixel includes Color Index Pigment Green 7 and Color Index Pigment Yellow 150. It is preferable that the composition for a green pixel includes 50 to 240 parts by mass of C. I. Pigment Yellow 150 with respect to 100 parts by mass of C. I. Pigment Green 7. The upper limit is preferably 200 parts by mass or less and more preferably 150 parts by mass or less. The lower limit is preferably 80 parts by mass or more and more preferably 100 parts by mass or more.

The composition for a green pixel may further contain a green colorant other than C. I. Pigment Green 7. Examples of other green colorants include those described in the section of the green pixel described above. Examples of a preferred aspect of the green colorant included in the composition for a green pixel include the aspects G1 and G2 described above, and from the viewpoint of color separation, the aspect G1 is preferable.

The composition for a green pixel can contain a yellow colorant other than C. I. Pigment Yellow 150. Examples of the yellow colorant other than C. I. Pigment Yellow 150 include the yellow colorant 1 described above, and from the viewpoint of color separation and light resistance, C. I. Pigment Yellow 129, 138, 139, or 185 is preferable. Examples of a preferred aspect of the yellow colorant included in the composition for a green pixel include the aspects Y1 and Y2 described above, and from the viewpoint of light resistance, the aspect Y1 is preferable.

The composition for a green pixel may contain a colorant (hereinafter, also referred to as other colorants) other than the green colorant and the yellow colorant, but from the viewpoint of color separation, it is particularly preferable that the composition for a green pixel does not substantially contain the other colorants. Examples of the other colorants include chromatic colorants such as a red colorant, a blue colorant, a violet colorant, and an orange colorant. The case where the green pixel does not substantially contain the other colorants means that a content of the other colorants in colorants included in the green pixel is less than 0.5 mass %, preferably less than 0.1 mass % and more preferably 0 mass %.

A content of the colorant in the total solid content of the composition for a green pixel is preferably 15 mass % or more, more preferably 20 mass % or more, and still more preferably 25 mass % or more. The upper limit is preferably 60 mass % or less, more preferably 50 mass % or less, and still more preferably 40 mass % or less.

It is preferable that the composition for a green pixel contains 50 to 240 parts by mass of the yellow colorant with respect to 100 parts by mass of the green colorant. The upper limit is preferably 200 parts by mass or less and more preferably 150 parts by mass or less. The lower limit is preferably 80 parts by mass or more and more preferably 100 parts by mass or more.

In addition, a total content of the green colorant and the yellow colorant in the total amount of colorants included in the composition for a green pixel is preferably 50 to 100 mass %, more preferably 75 to 100 mass %, and still more preferably 90 to 100 mass %. In addition, a total content of C. I. Pigment Green 7 and C. I. Pigment Yellow 150 in the total amount of colorants included in the composition for a green pixel is preferably 50 to 100 mass %, more preferably 75 to 100 mass %, and still more preferably 90 to 100 mass %. In addition, the total content of C. I. Pigment Green 7 and C. I. Pigment Yellow 150 in the total solid content of the composition for a green pixel is preferably 15 to 60 mass %, more preferably 22 to 52 mass %, and still more preferably 29 to 45 mass %.

<<Polymerizable Compound>>

The composition for a green pixel preferably contains a polymerizable compound. Examples of the polymerizable compound include a compound having an ethylenically unsaturated bond-containing group. Examples of the ethylenically unsaturated bond-containing group include a vinyl group, a (meth)allyl group, and a (meth)acryloyl group. The polymerizable compound is preferably a compound (radical polymerizable compound) which can be polymerized by radicals.

Any chemical forms of a monomer, a prepolymer, an oligomer, or the like may be used as the polymerizable compound, but a monomer is preferable. The molecular weight of the polymerizable compound is preferably 100 to 3000. The upper limit is preferably 2000 or less and more preferably 1500 or less. The lower limit is preferably 150 or more and more preferably 250 or more.

The polymerizable compound is preferably a compound including three or more ethylenically unsaturated bond-containing groups, and more preferably a compound including four or more ethylenically unsaturated bond-containing groups. According to this aspect, curing properties by exposure are good. From the viewpoint of temporal stability of the composition for a green pixel, the upper limit of the number of ethylenically unsaturated bond-containing groups is preferably 15 or less, more preferably 10 or less, and still more preferably 6 or less. In addition, as the polymerizable compound, a (meth)acrylate compound having 3 or more functional groups is preferable, a (meth)acrylate compound having 3 to 15 functional groups is more preferable, a (meth)acrylate compound having 3 to 10 functional groups is still more preferable, and a (meth)acrylate compound having 3 to 6 functional groups is particularly preferable.

As the polymerizable compound, dipentaerythritol tri(meth)acrylate (as a commercially available product, KAYARAD D-330 manufactured by Nippon Kayaku Co., Ltd.), dipentaerythritol tetra(meth)acrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which these (meth)acryloyl groups are bonded through an ethylene glycol and/or a propylene glycol residue (for example, SR454 and SR499 which are commercially available products from Sartomer) is preferable. In addition, as the polymerizable compound, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

As the polymerizable compound, it is also preferable to use a trifunctional (meth)acrylate compound such as trimethylolpropane tri(meth)acrylate, trimethylolpropane propyleneoxide-modified-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3 L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable compound, a polymerizable compound having an acid group can also be used. By using a polymerizable compound having an acid group, it is possible to suppress generation of development residues. Examples of the acid group include a carboxyl group, a sulfo group, and a phosphoric acid group, and a carboxyl group is preferable. Examples of a commercially available product of the polymerizable compound having an acid group include ARONIX M-305, M-510, M-520, and ARONIX TO-2349 (manufactured by TOAGOSEI CO., LTD.). An acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility of a composition layer in a developer is good, and in a case where the acid value of the polymerizable compound is 40 mgKOH/g or less, it is advantageous in production and handling.

As the polymerizable compound, a polymerizable compound having a caprolactone structure can also be used. Examples of the polymerizable compound having a caprolactone structure include DPCA-20, DPCA-30, DPCA-60, and DPCA-120, each of which is commercially available as KAYARAD DPCA series from Nippon Kayaku Co., Ltd.

As the polymerizable compound, a polymerizable compound having an alkyleneoxy group can also be used. The polymerizable compound having an alkyleneoxy group is preferably a polymerizable compound having an ethyleneoxy group and/or a propyleneoxy group, more preferably a polymerizable compound having an ethyleneoxy group, and still more preferably a trifunctional to hexafunctional (meth)acrylate compound having 4 to 20 ethyleneoxy groups. Examples of a commercially available product of the polymerizable compound having an alkyleneoxy group include SR-494 (manufactured by Sartomer), which is a tetrafunctional (meth)acrylate having 4 ethyleneoxy groups, and KAYARAD TPA-330 (manufactured by Nippon Kayaku Co., Ltd.), which is a trifunctional (meth)acrylate having 3 isobutyleneoxy groups.

As the polymerizable compound, a polymerizable compound having a fluorene skeleton can also be used. Examples of a commercially available product of the polymerizable compound having a fluorene skeleton include OGSOL EA-0200, EA-0300 (manufactured by Osaka Gas Chemicals Co., Ltd., (meth)acrylate monomer having a fluorene skeleton).

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

The urethane acrylates described in JP1973-041708B (JP-S48-041708B), JP1976-037193A (JP-S51-037193A), JP1990-032293B (JP-H02-032293B), or JP1990-016765B (JP-H02-016765B), or the urethane compounds having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) are also suitable as the polymerizable compound. In addition, the polymerizable compounds having an amino structure or a sulfide structure in the molecule, described in JP1988-277653A (JP-S63-277653A), JP1988-260909A (JP-S63-260909A), or JP1989-105238A (JP-H01-105238A), are also preferably used. In addition, as the polymerizable compound, commercially available products such as UA-7200 (manufactured by Shin-Nakamura Chemical Co., Ltd.), DPHA-40H (manufactured by Nippon Kayaku Co., Ltd.), and UA-306H, UA-306 T, UA-306I, AH-600, T-600, AI-600, and LINC-202UA (manufactured by KYOEISHA CHEMICAL Co., Ltd.) can also be used.

A content of the polymerizable compound in the total solid content of the composition for a green pixel is preferably 5 to 35 mass %. The upper limit is preferably 30 mass % or less and more preferably 25 mass % or less. The lower limit is preferably 7.5 mass % or more and more preferably 10 mass % or more.

<<Photopolymerization Initiator>>

The composition for a green pixel preferably contains a photopolymerization initiator. The photopolymerization initiator is not particularly limited, and can be appropriately selected from known photopolymerization initiators. For example, a compound having photosensitivity to rays in a range from an ultraviolet range to a visible range is preferable. The photopolymerization initiator is preferably a photoradical polymerization initiator.

Examples of the photopolymerization initiator include halogenated hydrocarbon derivatives (such as a compound having a triazine skeleton and a compound having an oxadiazole skeleton), acylphosphine compounds such as acylphosphine oxide, a hexaaryl biimidazole compound, oxime compounds such as an oxime derivative, an organic peroxide, a thio compound, a ketone compound, an aromatic onium salt, a ketoxime ether compound, an aminoalkylphenone compound, a hydroxyalkylphenone compound, and a phenylglyoxylate compound. With regard to the specific examples of the photopolymerization initiator, reference can be made to paragraph Nos. 0265 to 0268 of JP2013-029760A and JP6301489B, the contents of which are incorporated herein by reference. The photopolymerization initiator is preferably a photopolymerization initiator containing an oxime compound, and more preferably a photopolymerization initiator containing an oxime compound and a hydroxyalkylphenone compound.

Examples of the phenylglyoxylate compound include phenylglyoxylic acid methyl ester. Examples of a commercially available product thereof include Omnirad MBF (manufactured by IGM Resins B.V.) and Irgacure MBF (manufactured by BASF).

Examples of the acylphosphine compound include the acylphosphine compound described in JP4225898B. Specific examples thereof include bis(2,4,6-trimethylbenzoyl)-phenylphosphine oxide. Examples of a commercially available product of the acylphosphine compound include Omnirad 819 and Omnirad TPO (both of which are manufactured by IGM Resins B.V.), and Irgacure 819 and Irgacure TPO (both of which are manufactured by BASF).

Examples of the aminoalkylphenone compound include the aminoalkylphenone compound described in JP1998-291969A (JP-H10-291969A). In addition, examples of a commercially available product of the aminoalkylphenone compound include Omnirad 907, Omnirad 369, Omnirad 369E, and Omnirad 379EG (all of which are manufactured by IGM Resins B.V.), Irgacure 907, Irgacure 369, Irgacure 369E, and Irgacure 379EG (all of which are manufactured by BASF).

Examples of the hydroxyalkylphenone compound include a compound represented by Formula (V).

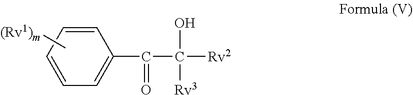

In the formula, Rv¹ represents a substituent, Rv² and Rv³ each independently represent a hydrogen atom or a substituent, Rv² and Rv³ may be bonded to each other to form a ring, and m represents an integer of 0 to 5.

Examples of the substituent represented by Rv¹ include an alkyl group (preferably an alkyl group having 1 to 10 carbon atoms) and an alkoxy group (preferably an alkoxy group having 1 to 10 carbon atoms). The alkyl group and alkoxy group are preferably linear or branched, and more preferably linear. The alkyl group and alkoxy group represented by Rv¹ may be unsubstituted or may have a substituent. Examples of the substituent include a hydroxy group and a group having a hydroxyalkylphenone structure. Examples of the group having a hydroxyalkylphenone structure include a group of a structure in which, in Formula (V), one hydrogen atom is removed from the benzene ring bonded with Rv¹ or from Rv¹.

Rv² and Rv³ each independently represent a hydrogen atom or a substituent. As the substituent, an alkyl group (preferably an alkyl group having 1 to 10 carbon atoms) is preferable. In addition, Rv² and Rv³ may be bonded to each other to form a ring (preferably a ring having 4 to 8 carbon atoms and more preferably an aliphatic ring having 4 to 8 carbon atoms). The alkyl group is preferably linear or branched, and more preferably linear.

Specific examples of the compound represented by Formula (V) include the following compounds.

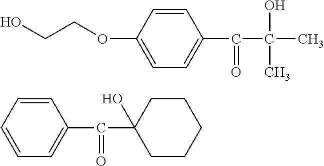

Examples of a commercially available product of the hydroxyalkylphenone compound include Omnirad 184, Omnirad 1173, Omnirad 2959, and Omnirad 127 (all of which are manufactured by IGM Resins B.V.), Irgacure 184, Irgacure 1173, Irgacure 2959, and Irgacure 127 (all of which are manufactured by BASF).

Examples of the oxime compound include the compounds described in JP2001-233842A, the compounds described in JP2000-080068A, the compounds described in JP2006-342166A, the compounds described in J. C. S. Perkin II (1979, pp. 1653 to 1660), the compounds described in J. C. S. Perkin II (1979, pp. 156 to 162), the compounds described in Journal of Photopolymer Science and Technology (1995, pp. 202 to 232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and the compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include Irgacure OXE01, Irgacure OXE02, Irgacure OXE03, and Irgacure OXE04 (all of which are manufactured by BASF), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product thereof include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include the compounds described in JP2014-137466A.

As the photopolymerization initiator, an oxime compound having a skeleton in which at least one benzene ring of a carbazole ring is a naphthalene ring can also be used. Specific examples of such an oxime compound include the compounds described in WO2013/083505A.

An oxime compound having a fluorine atom can also be used as the photopolymerization initiator. The oxime compound including a fluorine atom is preferably a compound represented by Formula (OX-1).

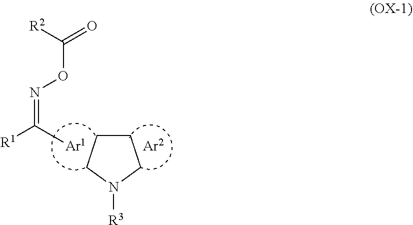

In Formula (OX-1), Ar¹ and Ar² each independently represent an aromatic hydrocarbon ring which may have a substituent, R¹ represents an aryl group having a group including a fluorine atom, and R² and R³ each independently represent an alkyl group or an aryl group.

The aromatic hydrocarbon ring represented by Ar¹ and Ar² in Formula (OX-1) may be a single ring or a fused ring. The number of carbon atoms constituting the ring of the aromatic hydrocarbon ring is preferably 6 to 20, more preferably 6 to 15, and particularly preferably 6 to 10. The aromatic hydrocarbon ring is preferably a benzene ring or a naphthalene ring. Among these, Ar¹ is preferably a benzene ring. Ar² is preferably a benzene ring or a naphthalene ring, and more preferably a naphthalene ring.

Examples of the substituent which may be included in Ar¹ and Ar² include an alkyl group, an aryl group, a heterocyclic group, a nitro group, a cyano group, a halogen atom, —OR^{X1}, —SR^{X1}, —COR^{X1}, —COOR^{X1}, —OCOR^{X1}, —NR^{X1}R^{X2}, —NHCOR^{X1}, —CONR^{X1}R^{X2}, —NHCONR^{X1}R^{X2}, —NHCOOR^{X1}, —SO₂R^{X1}, —SO₂OR^{X1}, and —NHSO₂R^{X1}. R^{X1} and R^{X2} each independently represent a hydrogen atom, an alkyl group, an aryl group, or a heterocyclic group.

Examples of the halogen atom include a fluorine atom, a chlorine atom, a bromine atom, and an iodine atom, and a fluorine atom is preferable. The number of carbon atoms in the alkyl group as the substituent and in the alkyl group represented by R^{X1} and R^{X2} is preferably 1 to 30. The alkyl group may be linear, branched, or cyclic, and is preferably linear or branched. In the alkyl group, a part or all of the hydrogen atoms may be substituted with halogen atoms (preferably fluorine atoms). In addition, in the alkyl group, a part or all of the hydrogen atoms may be substituted with the above-described substituents. The number of carbon atoms in the aryl group as the substituent and in the aryl group represented by R^{X1} and R^{X2} is preferably 6 to 20, more preferably 6 to 15, and still more preferably 6 to 10. The aryl group may be a single ring or a fused ring. In addition, in the aryl group, a part or all of the hydrogen atoms may be substituted with the above-described substituents. The heterocyclic group as the substituent and the heterocyclic group represented by R^{X1} and R^{X2} are preferably a 5-membered ring or a 6-membered ring. The heterocyclic group may be a single ring or a fused ring. The number of carbon atoms constituting the heterocyclic group is preferably 3 to 30, more preferably 3 to 18, and more preferably 3 to 12. The number of heteroatoms constituting the heterocyclic group is preferably 1 to 3. The heteroatom constituting the heterocyclic group is preferably a nitrogen atom, an oxygen atom, or a sulfur atom. In addition, in the heterocyclic group, a part or all of the hydrogen atoms may be substituted with the above-described substituents.

The aromatic hydrocarbon ring represented by Ar¹ is preferably an unsubstituted aromatic hydrocarbon ring. The aromatic hydrocarbon ring represented by Ar² preferably has a substituent. As the substituent, —COR^{X1} is preferable. R^{X1} is preferably an alkyl group, an aryl group, or a heterocyclic group, and more preferably an aryl group. The aryl group may have a substituent or may be unsubstituted. Examples of the substituent include an alkyl group having 1 to 10 carbon atoms.

R¹ in Formula (OX-1) represents an aryl group having a group including a fluorine atom. The number of carbon atoms in the aryl group is preferably 6 to 20, more preferably 6 to 15, and still more preferably 6 to 10. The group including a fluorine atom is preferably an alkyl group having a fluorine atom (hereinafter, also referred to as a fluorine-containing alkyl group) or a group including an alkyl group having a fluorine atom (hereinafter, also referred to as a fluorine-containing group). As the fluorine-containing group, at least one group selected from —OR^{F1}, —SR^{F1}, —COR^{F1}, —COOR^{F1}, —OCOR^{F1}, —NR^{F1}R^{F2}, —NHCOR^{F1}, —CONR^{F1}R^{F2}, —NHCONR^{F1}R^{F2}, —NHCOOR^{F1}, —SO₂R^{F1}, —SO₂OR^{F1}, and —NHSO₂R^{F1} is preferable. R^{F1} represents a fluorine-containing alkyl group, and R^{F2} represents a hydrogen atom, an alkyl group, a fluorine-containing alkyl group, an aryl group, or a heterocyclic group. The fluorine-containing group is preferably —OR^{F1}.

The number of carbon atoms in the fluorine-containing alkyl group represented by R^{F1} and R^{F2} and in the alkyl group represented by R^{F2} is preferably 1 to 20, more preferably 1 to 15, still more preferably 1 to 10, and particularly preferably 1 to 4. The fluorine-containing alkyl group and the alkyl group may be linear, branched, or cyclic, and is preferably linear or branched. A substitution rate of fluorine atoms in the fluorine-containing alkyl group is preferably 40% to 100%, more preferably 50% to 100%, and still more preferably 60% to 100%. The substitution rate of fluorine atoms refers to a ratio (%) of the number substituted with fluorine atoms to the total number of hydrogen atoms in the alkyl group.

The number of carbon atoms in the aryl group represented by R^{F2} is preferably 6 to 20, more preferably 6 to 15, and still more preferably 6 to 10.

The heterocyclic group represented by R^{F2} is preferably a 5-membered ring or a 6-membered ring. The heterocyclic group may be a single ring or a fused ring. The fused number is preferably 2 to 8, more preferably 2 to 6, still more preferably 3 to 5, and particularly preferably 3 or 4. The number of carbon atoms constituting the heterocyclic group is preferably 3 to 40, more preferably 3 to 30, and more preferably 3 to 20. The number of heteroatoms constituting the heterocyclic group is preferably 1 to 3. The heteroatom constituting the heterocyclic group is preferably a nitrogen atom, an oxygen atom, or a sulfur atom, and more preferably a nitrogen atom.

The group including a fluorine atom preferably has a terminal structure represented by Formula (1) or (2). * in the formulae represents a bonding site.

*—CHF₂ (1)

*—CF₃ (2)

R² in Formula (OX-1) represents an alkyl group or an aryl group, and is preferably an alkyl group. The alkyl group and the aryl group may be unsubstituted or may have a substituent. Examples of the substituent include the substituents described as the substituent which may be included in Ar¹ and Ar². The number of carbon atoms in the alkyl group is preferably 1 to 20, more preferably 1 to 15, still more preferably 1 to 10, and particularly preferably 1 to 4. The alkyl group may be linear, branched, or cyclic, and is preferably linear or branched. The number of carbon atoms in the aryl group is preferably 6 to 20, more preferably 6 to 15, and still more preferably 6 to 10.

R³ in Formula (OX-1) represents an alkyl group or an aryl group, and is preferably an alkyl group. The alkyl group and the aryl group may be unsubstituted or may have a substituent. Examples of the substituent include the substituents described as the substituent which may be included in Ar¹ and Ar². The number of carbon atoms in the alkyl group represented by R³ is preferably 1 to 20, more preferably 1 to 15, and still more preferably 1 to 10. The alkyl group may be linear, branched, or cyclic, and is preferably linear or branched. The number of carbon atoms in the aryl group represented by R³ is preferably 6 to 20, more preferably 6 to 15, and still more preferably 6 to 10.

Specific examples of the oxime compound having a fluorine atom include the compounds described in JP2010-262028A, the compounds 24, and 36 to 40 described in JP2014-500852A, and the compound (C-3) described in JP2013-164471A.

An oxime compound having a nitro group can be used as the photopolymerization initiator. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

In the present invention, as the photopolymerization initiator, an oxime compound in which a substituent having a hydroxy group is bonded to a carbazole skeleton can also be used. Examples of such a photopolymerization initiator include compounds described in WO2019/088055A.

Specific examples of the oxime compound preferably used are shown below, but the present invention is not limited thereto.

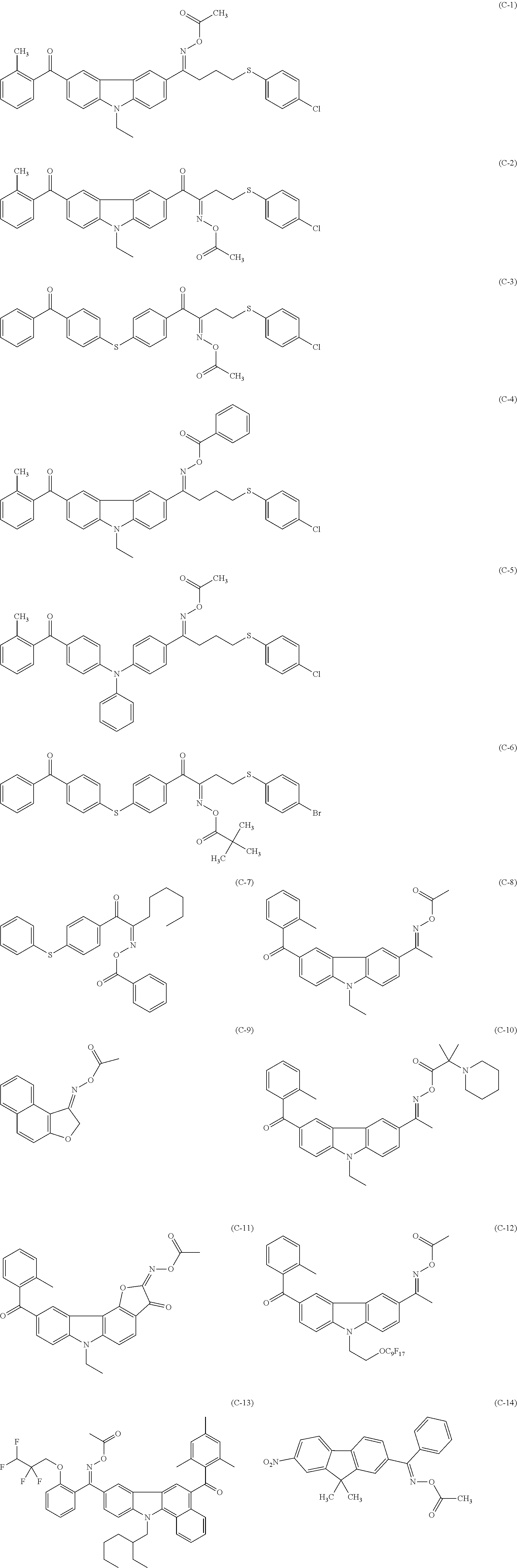

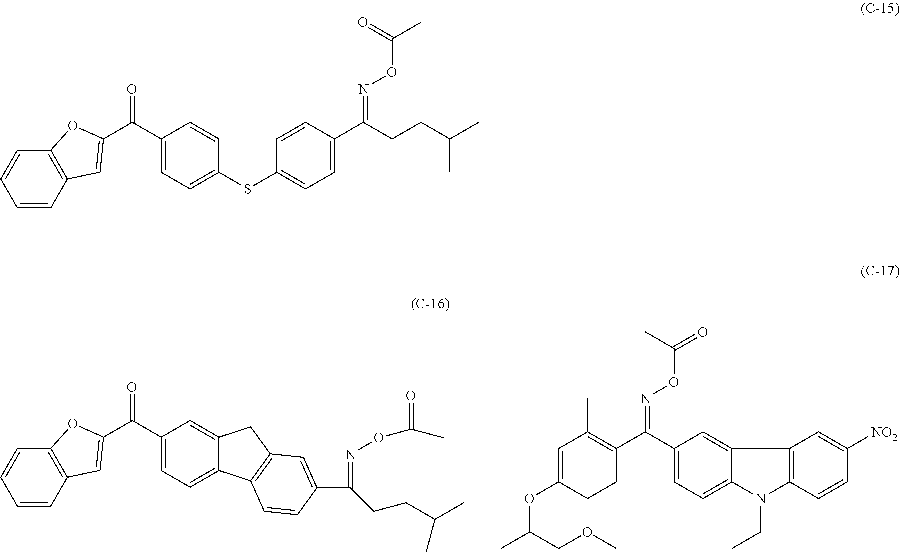 [SMILES: CC(=O)O/N=C(\CCC(C)C)c1ccc(Sc2ccc(C(=O)c3cc4ccccc4o3)cc2)cc1 ; "(C-16)" ; CC(=O)O/N=C(\CCC(C)C)c1ccc2c(c1)Cc1cc(C(=O)c3cc4ccccc4o3)ccc1-2 ; CCn1c2ccc(/C(=N\OC(C)=O)C3=C(C)C=C(OC(C)COC)CC3)cc2c2cc([N+](=O)[O-])ccc21]

As the photopolymerization initiator, it is also preferable that a photopolymerization initiator A1 having a light absorption coefficient of 1.0×10³ mL/g·cm or more at a wavelength of 365 nm in methanol, and a photopolymerization initiator A2 having a light absorption coefficient of 1.0×10² mL/g·cm or less at a wavelength of 365 nm in methanol and having a light absorption coefficient of 1.0×10³ mL/g·cm or more at a wavelength of 254 nm in methanol are used in combination. According to this aspect, the composition for a green pixel is easily cured sufficiently by exposure, high flatness is obtained in low-temperature process (for example, a process at a temperature of 150° C. or lower, preferably a temperature of 120° C. or lower, throughout entire steps), and a pixel having excellent characteristics such as light resistance and solvent resistance can be formed. As the photopolymerization initiator A1 and the photopolymerization initiator A2, compounds having the above-described light absorption coefficient are preferably selected and used from the above-described compounds.

In the present specification, the light absorption coefficient of a photopolymerization initiator at the above-described wavelength is a value measured as follows. That is, the light absorption coefficient is obtained by preparing a measurement solution by dissolving the photopolymerization initiator in methanol, and measuring absorbance of the measurement solution. Specifically, the measurement solution is put into a glass cell having a width of 1 cm, absorbance is measured using a UV-Vis-NIR spectrometer (Cary 5000) manufactured by Agilent Technologies Inc., and the light absorption coefficient (mL/g·cm) at a wavelength of 365 nm and a wavelength of 254 nm is obtained by applying the following expression.

$$ε = \frac{A}{c l}$$

In the expression, c represents a light absorption coefficient (mL/g·cm), A represents an absorbance, c represents a concentration (g/mL) of the photopolymerization initiator, and 1 represents an optical path length (cm).

The light absorption coefficient of the photopolymerization initiator A1 at a wavelength of 365 nm in methanol is 1.0×10³ mL/g·cm or more, preferably 1.0×10⁴ mL/g·cm or more, more preferably 1.1×10⁴ mL/g·cm or more, still more preferably 1.2×10⁴ to 1.0×10⁵ mL/g·cm, even more preferably 1.3×10⁴ to 5.0×10⁴ mL/g·cm, and particularly preferably 1.5×10⁴ to 3.0×10⁴ mL/g·cm.

In addition, the light absorption coefficient of the photopolymerization initiator A1 at a wavelength of 254 nm in methanol is preferably 1.0×10⁴ to 1.0×10⁵ mL/g·cm, more preferably 1.5×10⁴ to 9.5×10⁴ mL/g·cm, and still more preferably 3.0×10⁴ to 8.0×10⁴ mL/g·cm.

As the photopolymerization initiator A1, an oxime compound, an aminoalkylphenone compound, or an acylphosphine compound is preferable, an oxime compound or an acylphosphine compound is more preferable, an oxime compound is still more preferable, and from the viewpoint of compatibility with other components included in the composition, an oxime compound including a fluorine atom is particularly preferable. As the oxime compound including a fluorine atom, the above-described compound represented by Formula (OX-1) is preferable. Specific examples of the photopolymerization initiator A1 include 1,2-octanedione, 1-[4-(phenylthio)-,2-(O-benzoyloxime)] (as a commercially available product, for example, Irgacure OXE01 manufactured by BASF), ethanone, 1-[9-ethyl-6-(2-methylbenzoyl)-9H-carbazol-3-yl]-, 1-(O-acetyloxime) (as a commercially available product, for example, Irgacure OXE02 manufactured by BASF), and (C-13), (C-14), and (C-17), which are shown in the specific examples of the above-described oxime compound.

The light absorption coefficient of the photopolymerization initiator A2 at a wavelength of 365 nm in methanol is 1.0×10² mL/g·cm or less, preferably 10 to 1.0×10² mL/g cm, and more preferably 20 to 1.0×10² mL/g·cm. In addition, the difference between the light absorption coefficient of the photopolymerization initiator A1 at a wavelength of 365 nm in methanol and the light absorption coefficient of the photopolymerization initiator A2 at a wavelength of 365 nm in methanol is 9.0×10² mL/g·cm or more, preferably 1.0×10³ mL/g·cm or more, more preferably 5.0×10³ to 3.0×10⁴ mL/g cm, and still more preferably 1.0×10⁴ to 2.0×10⁴ mL/g·cm. In addition, the light absorption coefficient of the photopolymerization initiator A2 at a wavelength of 254 nm in methanol is 1.0×10³ mL/g·cm or more, preferably 1.0×10³ to 1.0×10⁶ mL/g·cm, and more preferably 5.0×10³ to 1.0×10⁵ mL/g·cm.

As the photopolymerization initiator A2, a hydroxyalkylphenone compound, a phenylglyoxylate compound, an aminoalkylphenone compound, or an acylphosphine compound is preferable, a hydroxyalkylphenone compound or a phenylglyoxylate compound is more preferable, and a hydroxyalkylphenone compound is still more preferable. In addition, as the hydroxyalkylphenone compound, the above-described compound represented by Formula (V) is preferable. Specific examples of the photopolymerization initiator A2 include 1-hydroxy-cyclohexyl-phenyl-ketone and 1-[4-(2-hydroxyethoxy)-phenyl]-2-hydroxy-2-methyl-1-propan-1-one.

As a combination of the photopolymerization initiator A1 and the photopolymerization initiator A2, a combination in which the photopolymerization initiator A1 is an oxime compound and the photopolymerization initiator A2 is a hydroxyalkylphenone compound is preferable, a combination in which the photopolymerization initiator A1 is an oxime compound and the photopolymerization initiator A2 is the compound represented by Formula (V) is more preferable, and a combination in which the photopolymerization initiator A1 is an oxime compound including a fluorine atom and the photopolymerization initiator A2 is the compound represented by Formula (V) is particularly preferable.

In addition, as the photopolymerization initiator, it is also preferable to use Irgacure OXE01 (manufactured by BASF) and/or Irgacure OXE02 (manufactured by BASF) and Omnirad 2959 (manufactured by IGM Resins B.V.) in combination.

A content of the photopolymerization initiator in the total solid content of the composition for a green pixel is preferably 3 to 25 mass %. The lower limit is preferably 5 mass % or more, more preferably 7.5 mass % or more, still more preferably 8 mass % or more, even still more preferably 9 mass % or more, and particularly preferably 10 mass % or more. The upper limit is preferably 20 mass % or less, more preferably 17.5 mass % or less, and still more preferably 15 mass % or less. The photopolymerization initiator may be used singly or in combination of two or more kinds thereof. In a case where two or more kinds thereof are used in combination, the total amount thereof is preferably within the above-described range.

In a case where the above-described photopolymerization initiator A1 is used as the photopolymerization initiator, the content of the photopolymerization initiator A1 in the total solid content of the composition for a green pixel is preferably 3 to 25 mass %. The lower limit is preferably 5 mass % or more, more preferably 7.5 mass % or more, still more preferably 8 mass % or more, even still more preferably 9 mass % or more, and particularly preferably 10 mass % or more. The upper limit is preferably 20 mass % or less, more preferably 17.5 mass % or less, and still more preferably 15 mass % or less. In a case where the content of the photopolymerization initiator A1 is within the above-described range, adhesiveness of the pixel after development to the support can be improved.

In a case where the above-described photopolymerization initiator A2 is used as the photopolymerization initiator, the content of the photopolymerization initiator A2 in the total solid content of the composition for a green pixel is preferably 0.1 to 10.0 mass %. The lower limit is preferably 0.5 mass % or more, more preferably 1.0 mass % or more, and still more preferably 1.5 mass % or more. The upper limit is preferably 9.0 mass % or less, more preferably 8.0 mass % or less, and still more preferably 7.0 mass % or less. In a case where the content of the photopolymerization initiator A2 is within the above-described range, solvent resistance of the pixel after development can be improved.

In a case where the above-described photopolymerization initiator A1 and the above-described photopolymerization initiator A2 are used as the photopolymerization initiator, it is preferable that the composition for a green pixel contains 50 to 200 parts by mass of the photopolymerization initiator A2 with respect to 100 parts by mass of the photopolymerization initiator A1. The upper limit is preferably 175 parts by mass or less and more preferably 150 parts by mass or less. The lower limit is preferably 60 parts by mass or more and more preferably 70 parts by mass or more. According to this aspect, a pixel having excellent characteristics such as solvent resistance can be formed by low-temperature process (for example, process at a temperature of 150° C. or lower, preferably a temperature of 120° C. or lower, throughout entire steps). In a case where two or more kinds of the photopolymerization initiators A1 and two or more kinds of the photopolymerization initiators A2 are used in combination, it is preferable that the total amount of each satisfies the above-described requirements.

In a case where the above-described photopolymerization initiator A1 and the above-described photopolymerization initiator A2 are used as the photopolymerization initiator, the total content of the photopolymerization initiator A1 and the photopolymerization initiator A2 in the total solid content of the composition for a green pixel is preferably 3.1 to 25 mass %. The lower limit is preferably 4 mass % or more, preferably 5 mass % or more, more preferably 7.5 mass % or more, still more preferably 8 mass % or more, even more preferably 9 mass % or more, and particularly preferably 10 mass % or more. The upper limit is preferably 20 mass % or less, more preferably 17.5 mass % or less, and still more preferably 15 mass % or less.

<<Resin>>

The composition for a green pixel preferably contains a resin. The resin is blended in, for example, an application for dispersing pigments (C. I. Pigment Green 7, C. I. Pigment Yellow 150, and the like) in the composition for a green pixel or an application as a binder. Mainly, a resin which is used for dispersing the pigment in the composition for a green pixel is also referred to as a dispersant. However, such applications of the resin are merely exemplary, and the resin can also be used for other purposes in addition to such applications.

A weight-average molecular weight (Mw) of the resin is preferably 2000 to 2000000. The upper limit is preferably 1000000 or less and more preferably 500000 or less. The lower limit is preferably 3000 or more, more preferably 4000 or more, and still more preferably 5000 or more.

Examples of the resin include a (meth)acrylic resin, a (meth)acrylamide resin, an epoxy resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, a styrene resin, and a siloxane resin. In addition, resins described in paragraph Nos. 0041 to 0060 of JP2017-206689A, resins described in paragraph Nos. 0022 to 0071 of JP2018-010856A, resins described in JP2017-057265A, resins described in JP2017-032685A, resins described in JP2017-075248A, and resins described in JP2017-066240A can also be used.

It is preferable that the resin included in the composition for a green pixel includes an alkali-soluble resin. As the alkali-soluble resin, a resin having an acid group is preferable. Examples of the acid group include a phenolic hydroxy group, a carboxyl group, a sulfo group, a phosphoric acid group, and a phosphonic acid group.

The acid value of the alkali-soluble resin is preferably 30 to 500 mgKOH/g. The lower limit is more preferably 50 mgKOH/g or more and still more preferably 70 mgKOH/g or more. The upper limit is more preferably 400 mgKOH/g or less, still more preferably 200 mgKOH/g or less, even still more preferably 150 mgKOH/g or less, and most preferably 120 mgKOH/g or less.

The alkali-soluble resin may have a repeating unit derived from a maleimide compound. Examples of the maleimide compound include N-alkylmaleimide and N-arylmaleimide. Examples of the repeating unit derived from a maleimide compound include a repeating unit represented by Formula (C-mi).

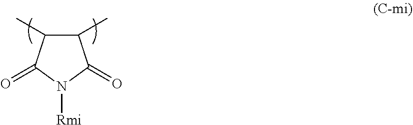

In Formula (C-mi), Rmi represents an alkyl group or an aryl group. The number of carbon atoms in the alkyl group is preferably 1 to 20. The alkyl group may be linear, branched, or cyclic. The number of carbon atoms in the aryl group is preferably 6 to 20, more preferably 6 to 15, and still more preferably 6 to 10. Rmi is preferably an aryl group.

As the resin, a resin including a repeating unit derived from a compound represented by Formula (ED1) and/or a compound represented by Formula (ED2) (hereinafter, these compounds will also be referred to as an “ether dimer”) is also preferable.

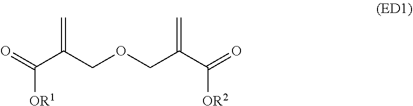

In Formula (ED1), R¹ and R² each independently represent a hydrogen atom or a hydrocarbon group having 1 to 25 carbon atoms, which may have a substituent.

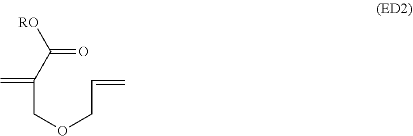

In Formula (ED2), R represents a hydrogen atom or an organic group having 1 to 30 carbon atoms. With regard to details of Formula (ED2), reference can be made to the description in JP2010-168539A, the contents of which are incorporated herein by reference. Specific examples of the ether dimer can be found in paragraph No. 0317 of JP2013-029760A, the contents of which are incorporated herein by reference.

The resin also preferably includes a resin including a repeating unit having a polymerizable group.

The resin also preferably includes a resin including a repeating unit derived from a compound represented by Formula (X).

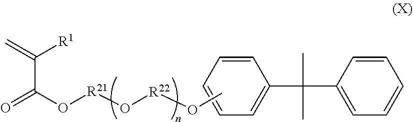

In the formula, R¹ represents a hydrogen atom or a methyl group, R²¹ and R²² each independently represent an alkylene group, and n represents an integer of 0 to 15. The number of carbon atoms in the alkylene group represented by R²¹ and R²² is preferably 1 to 10, more preferably 1 to 5, still more preferably 1 to 3, and particularly preferably 2 or 3. n represents an integer of 0 to 15, and is preferably an integer of 0 or 5, more preferably an integer of 0 to 4, and still more preferably an integer of 0 to 3.

Examples of the compound represented by Formula (X) include ethylene oxide- or propylene oxide-modified (meth)acrylate of para-cumylphenol. Examples of a commercially available product thereof include ARONIX M-110 (manufactured by TOAGOSEI CO., LTD.).

As the resin, it is also preferable to contain a resin (hereinafter, also referred to as a resin BI) which has a repeating unit including a blocked isocyanate group. According to this aspect, more excellent low temperature curing properties can be obtained, and a sufficiently cured pixel can be formed even by heating at a relatively low temperature.

The blocked isocyanate group included in the resin BI is preferably a group capable of generating an isocyanate group by heating, and more preferably a group capable of generating an isocyanate group by heating at 70° C. to 150° C. Examples of the blocked isocyanate group include a group having a structure in which an isocyanate group is chemically protected by a blocking agent. The blocked isocyanate group is a group having a structure in which an isocyanate group is protected by a compound called a blocking agent. Although the blocked isocyanate group does not exhibit reactivity as the isocyanate group at normal temperature (for example, 10° C. to 30° C.), the blocked isocyanate group is a group having a structure in which the blocking agent is eliminated from the blocked isocyanate group by heating or the like to generate the isocyanate group.

The blocked isocyanate group included in the resin BI is more preferably a group capable of generating an isocyanate group by heating at 70° C. to 150° C. That is, the isocyanate generation temperature of the blocked isocyanate group (elimination temperature of the blocking agent) is preferably 70° C. to 150° C. From the viewpoint of storage stability, the lower limit of the isocyanate generation temperature is preferably 75° C. or higher and more preferably 80° C. or higher. From the viewpoint of curing properties, the upper limit of the isocyanate generation temperature is preferably 130° C. or lower and more preferably 120° C. or lower.

Examples of the blocking agent which protects the isocyanate group of the blocked isocyanate group include an oxime compound, a lactam compound, a phenol compound, an alcohol compound, an amine compound, an active methylene compound, a pyrazole compound, a mercaptan compound, an imidazole compound, and an imide compound, and from the viewpoint of easiness of protecting reaction and deprotecting reaction, an oxime compound, a lactam compound, an active methylene compound, or a pyrazole compound is preferable, an oxime compound, an active methylene compound, or a pyrazole compound is more preferable, and an oxime compound is still more preferable.

Examples of the oxime compound include acetoxime, formaldoxime, cyclohexane oxime, methyl ethyl ketone oxime, cyclohexanone oxime, and benzophenone oxime.

Examples of the lactam compound include ε-caprolactam and γ-butyrolactam.

Examples of the phenol compound include phenol, naphthol, cresol, xylenol, and halogen-substituted phenol.

Examples of the alcohol compound include methanol, ethanol, propanol, butanol, cyclohexanol, ethylene glycol monoalkyl ether, propylene glycol monoalkyl ether, and lactate alkyl.

Examples of the amine compound include primary amine and secondary amine. The amine compound may be an aromatic amine, an aliphatic amine, or a alicyclic amine, and specific examples thereof include aniline, diphenylamine, ethyleneimine, and polyethyleneimine.

Examples of the active methylene compound include diethyl malonate, dimethyl malonate, ethyl acetoacetate, and methyl acetoacetate.

Examples of the pyrazole compound include pyrazole, methylpyrazole, and dimethylpyrazole.

Examples of the mercaptan compound include alkyl mercaptan and aryl mercaptan.

Examples of the imidazole compound include imidazole, 1-methylimidazole, 1-ethylimidazole, 1,2-dimethylimidazole, 2-ethyl-4-methylimidazole, 1-benzyl-2-methylimidazole, and 1-benzyl-2-phenylimidazole.

Examples of the imide compound include maleimide, succinimide, phthalimide, and a derivative thereof.

A molecular weight of the blocking agent is preferably 50 to 200, more preferably 50 to 160, and still more preferably 50 to 120. In a case where the molecular weight of the blocking agent is 50 or more, the elimination of the blocking agent at room temperature can be suppressed, and storage stability of the composition for a green pixel can be improved. In a case where the molecular weight of the blocking agent is 200 or less, the blocking agent is easily eliminated by a heating treatment at a low temperature (for example, 150° C. or lower) to promote the curing reaction of the composition layer, and it is easy to form a sufficiently cured pixel. Therefore, it is easy to form a pixel in which color transfer with other colors is suppressed.

As the blocking agent, methyl ethyl ketone oxime, cyclohexanone oxime, acetoxime, diethyl malonate, ethyl acetoacetate, ε-caprolactam, γ-butyrolactam, or pyrazole is preferable, methyl ethyl ketone oxime, acetoxime, diethyl malonate, or pyrazole is more preferable, and methyl ethyl ketone oxime is still more preferable.

Examples of the repeating unit including a blocked isocyanate group include a repeating unit represented by Formula (Bi-1).

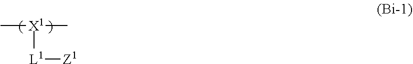

In Formula (Bi-1), X¹ represents a main chain of the repeating unit, L¹ represents a single bond or a divalent linking group, and Z¹ represents the blocked isocyanate group.

In Formula (Bi-1), the main chain of the repeating unit represented by X¹ is not particularly limited. It is not particularly limited as long as it is a linking group formed from a known polymerizable monomer. Examples thereof include a poly(meth)acrylic linking group, a polyalkyleneimine-based linking group, a polyester-based linking group, a polyurethane-based linking group, a polyuria-based linking group, a polyamide-based linking group, a polyether-based linking group, and a polystyrene-based linking group. Among these, a poly(meth)acrylic linking group or a polystyrene-based linking group is preferable, and a poly(meth)acrylic linking group is more preferable.

In Formula (Bi-1), examples of the divalent linking group represented by L¹ include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, and a group formed by a combination of two or more these groups. The alkylene group may be linear, branched, or cyclic, and is preferably linear or branched. In addition, the alkylene group may have a substituent or may be unsubstituted. Examples of the substituent include a hydroxy group and an alkoxy group.

In Formula (Bi-1), Z¹ represents the blocked isocyanate group.

In the resin BI, the content of the repeating unit including a blocked isocyanate group in all repeating units of the resin BI is preferably 45 mass % or more, more preferably 50 mass % or more, and still more preferably 55 mass % or more. The upper limit may be 100 mass %, 95 mass % or less, or 85 mass % or less.

The composition for a green pixel can contain a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70 mol % or more in a case where the total amount of the acid group and the basic group is 100 mol %, and more preferably a resin substantially consisting of only an acid group. The acid group included in the acidic dispersant (acidic resin) is preferably a carboxyl group. The acid value of the acidic dispersant (acidic resin) is preferably 10 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The basic group included in the basic dispersant is preferably an amino group.

Examples of the dispersant include polymer dispersants [for example, polyamide amine or a salt thereof, polycarboxylic acid or a salt thereof, high molecular weight unsaturated acid ester, modified polyurethane, modified polyester, modified poly(meth)acrylate, a (meth)acrylic copolymer, and a naphthalene sulfonic acid formalin condensate], polyoxyethylene alkylphosphate ester, polyoxyethylene alkyl amine, and alkanolamine. The polymer dispersant can be further classified into a linear polymer, a terminal-modified polymer, a graft polymer, and a block polymer according to the structure thereof. The polymer dispersant acts to prevent reaggregation by absorbing on a surface of particles such as the pigment. Therefore, examples of a preferred structure of the polymer dispersant include a terminal-modified polymer, a graft polymer, and a block polymer, each of which has an anchor site for adsorbing on the surface of particles such as pigments. In addition, dispersants described in paragraph Nos. 0028 to 0124 of JP2011-070156A or dispersants described in JP2007-277514A are preferably used.

A graft copolymer can also be used as the dispersant. With regard to details of the graft copolymer, reference can be made to the description in paragraph Nos. 0131 to 0160 of JP2012-137564A, the contents of which are incorporated herein by reference. In addition, as the dispersant, an oligoimine copolymer including a nitrogen atom at at least one of a main chain or a side chain can also be used. With regard to the oligoimine-based copolymer, reference can be made to the description in paragraph Nos. 0102 to 0174 of JP2012-255128A, the contents of which are incorporated herein by reference.

A commercially available product is also available as the dispersant, and specific examples thereof include DISPERBYK series (for example, DISPERBYK-111, 2001, and the like) manufactured by BYK-Chemie Japan K.K., Solsperse series (for example, Solsperse 20000, 76500, and the like) manufactured by Lubrizol Corporation, and AJISPER series manufactured by Ajinomoto Fine-Techno Co., Inc. In addition, products described in paragraph No. 0129 of JP2012-137564A and products described in paragraph No. 0235 of JP2017-194662A can also be used as the dispersant.

A content of the resin in the total solid content of the composition for a green pixel is preferably 5 to 50 mass %. The upper limit is preferably 40 mass % or less and more preferably 30 mass % or less. The lower limit is preferably 7.5 mass % or more and more preferably 10 mass % or more.

In addition, the content of the resin is preferably 25 to 500 parts by mass with respect to 100 parts by mass of the polymerizable compound. The upper limit is preferably 250 parts by mass or less and more preferably 150 parts by mass or less. The lower limit is preferably 50 parts by mass or more and more preferably 75 parts by mass or more.

In addition, the content of the alkali-soluble resin in the total amount of resins included in the composition for a green pixel is preferably 0.1 to 100 mass % and more preferably 5 to 100 mass %. The upper limit may be 90 mass % or less, 80 mass % or less, or 70 mass % or less.

In addition, the content of the alkali-soluble resin in the total solid content of the composition for a green pixel is preferably 5 to 50 mass %. The upper limit is preferably 40 mass % or less and more preferably 30 mass % or less. The lower limit is preferably 10 mass % or more and more preferably 12.5 mass % or more.

In addition, the content of the above-described resin BI in the total amount of resins included in the composition for a green pixel is preferably 0.1 to 100 mass % and more preferably 5 to 100 mass %. The upper limit may be 90 mass % or less, 80 mass % or less, or 70 mass % or less.

In addition, the content of the above-described resin BI in the total solid content of the composition for a green pixel is preferably 5 to 50 mass %. The upper limit is preferably 40 mass % or less and more preferably 30 mass % or less. The lower limit is preferably 10 mass % or more and more preferably 12.5 mass % or more.

<<Furyl Group-Containing Compound>>

The composition for a green pixel can contain a compound including a furyl group (hereinafter, also referred to as a furyl group-containing compound). According to this aspect, curing properties at low temperature are excellent. For example, in a case where the compound containing an ethylenically unsaturated bond-containing group is used as the polymerizable compound, since the furyl group of the furyl group-containing compound and the ethylenically unsaturated bond-containing group of the above-described polymerizable compound form a bond by Diels-Alder reaction even at a low temperature of 150° C., it is excellent in low temperature curing.

A structure of the furyl group-containing compound is not particularly limited as long as the compound includes a furyl group (group obtained by removing one hydrogen atom from furan). As the furyl group-containing compound, compounds described in paragraph Nos. 0049 to 0089 of JP2017-194662A can be used. In addition, as the furyl group-containing compound, compounds described in JP2000-233581A, JP1994-271558A, JP1994-293830A, JP1996-239421A, JP1998-508655A, JP2000-001529A, JP2003-183348A, JP2006-193628A, JP2007-186684A, JP2010-265377A, JP2011-170069A, and the like can also be used.

A content of the furyl group-containing compound in the total solid content of the composition for a green pixel is preferably 0.1 to 50 mass %. The lower limit is preferably 2.5 mass % or more, more preferably 5.0 mass % or more, and still more preferably 7.5 mass % or more. The upper limit is preferably 40 mass % or less, more preferably 30 mass % or less, and still more preferably 25 mass % or less.

<<Compound Having Epoxy Group>>

The composition for a green pixel can contain a compound having an epoxy group. As the compound having an epoxy group, a compound having two or more epoxy groups in one molecule is preferable. It is preferable to have 2 to 100 epoxy groups in one molecule. The upper limit may be, for example, 10 or less or 5 or less. An epoxy equivalent (=the molecular weight of the compound having an epoxy group/the number of epoxy groups) of the compound having an epoxy group is preferably 500 g/eq or less, more preferably 100 to 400 g/eq, and still more preferably 100 to 300 g/eq. The compound having an epoxy group may be either a low-molecular-weight compound (for example, a molecular weight of less than 1000) or a high-molecular-weight compound (macromolecule) (for example, a molecular weight of 1000 or more, and in a case of a polymer, a weight-average molecular weight of 1000 or more). A molecular weight (in a case of the polymer, a weight-average molecular weight) of the compound having an epoxy group is preferably 200 to 100000 and more preferably 500 to 50000. The upper limit of the molecular weight (in a case of the polymer, the weight-average molecular weight) is preferably 3000 or less, more preferably 2000 or less, and still more preferably 1500 or less.

As the epoxy compound having an epoxy group, compounds described in paragraph Nos. 0034 to 0036 of JP2013-011869A, paragraph Nos. 0147 to 0156 of JP2014-043556A, and paragraph Nos. 0085 to 0092 of JP2014-089408A, and compounds described in JP2017-179172A can also be used, the contents of which are incorporated herein by reference.

A content of the compound having an epoxy group in the total solid content of the composition for a green pixel is preferably 0.1 to 30 mass %. The lower limit is more preferably 0.5 mass % or more and still more preferably 1 mass % or more. The upper limit is more preferably 25 mass % or less and still more preferably 20 mass % or less. The compound having an epoxy group may be used singly or in combination of two or more kinds thereof. In a case where two or more kinds thereof are used in combination, the total amount thereof is preferably within the above-described range.

<<Solvent>>

The composition for a green pixel preferably contains a solvent. Examples of the solvent include an organic solvent. Basically, the solvent is not particularly limited as long as it satisfies the solubility of the respective components and the application properties of the composition. Examples of the organic solvent include an ester-based solvent, a ketone-based solvent, an alcohol-based solvent, an amide-based solvent, an ether-based solvent, and a hydrocarbon-based solvent. With regard to details thereof, reference can be made to the description in paragraph No. 0223 of WO2015/166779A, the contents of which are incorporated herein by reference. In addition, an ester-based solvent substituted with a cyclic alkyl group or a ketone-based solvent substituted with a cyclic alkyl group can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, and 3-butoxy-N,N-dimethylpropanamide. In this case, it may be preferable that the content of aromatic hydrocarbons (such as benzene, toluene, xylene, and ethylbenzene) as the solvent is low (for example, 50 parts per million (ppm) by mass or less, 10 ppm by mass or less, or 1 ppm by mass or less with respect to the total amount of the organic solvent) in consideration of environmental aspects and the like.

A solvent having a low metal content is preferably used as the solvent. For example, the metal content of the solvent is preferably 10 ppb (parts per billion) by mass or less. A solvent in which the metal content is at a level of ppt (parts per trillion) by mass may be used as desired, and such a high-purity solvent is provided by, for example, Toyo Kasei Kogyo Co., Ltd. (The Chemical Daily, Nov. 13, 2015).

Examples of a method for removing impurities such as a metal from the solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The solvent may include isomers (compounds having the same number of atoms and different structures). In addition, only one kind of isomers may be included, or a plurality of isomers may be included.

The organic solvent preferably has the content of peroxides of 0.8 mmol/L or less, and more preferably, the organic solvent does not substantially include peroxides.

A content of the solvent in the composition for a green pixel is preferably 60 to 95 mass %. The upper limit is preferably 90 mass % or less, more preferably 87.5 mass % or less, and still more preferably 85 mass % or less. The lower limit is preferably 65 mass % or more, more preferably 70 mass % or more, and still more preferably 75 mass % or more. The solvent may be used singly or in combination of two or more kinds thereof. In a case where two or more kinds thereof are used in combination, the total amount thereof is preferably within the above-described range.

<<Pigment Derivative>>

The composition for a green pixel can contain a pigment derivative. Examples of the pigment derivative include a compound having a structure in which a part of a chromophore is substituted with an acid group, a basic group, or a phthalimidomethyl group. Examples of the chromophore constituting the pigment derivative include a quinoline skeleton, a benzimidazolone skeleton, a diketopyrrolopyrrole skeleton, an azo skeleton, a phthalocyanine skeleton, an anthraquinone skeleton, a quinacridone skeleton, a dioxazine skeleton, a perinone skeleton, a perylene skeleton, a thioindigo skeleton, an isoindoline skeleton, an isoindolinone skeleton, a quinophthalone skeleton, a threne skeleton, and a metal complex skeleton. Among these, a quinoline skeleton, a benzimidazolone skeleton, a diketopyrrolopyrrole skeleton, an azo skeleton, a quinophthalone skeleton, an isoindoline skeleton, or a phthalocyanine skeleton is preferable, and an azo skeleton or a benzimidazolone skeleton is more preferable. As the acid group included in the pigment derivative, a sulfo group or a carboxyl group is preferable and a sulfo group is more preferable. As the basic group included in the pigment derivative, an amino group is preferable and a tertiary amino group is more preferable. Specific examples of the pigment derivative include compounds described in JP1981-118462A (JP-556-118462A), JP1988-264674A (JP-563-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraph Nos. 0086 to 0098 of WO2011/024896A, paragraph Nos. 0063 to 0094 of WO2012/102399A, paragraph No. 0082 of WO2017/038252A, paragraph No. 0171 of JP2015-151530A, paragraph Nos. 0162 to 0183 of JP2011-252065A, JP2003-081972A, JP5299151B, JP2015-172732A, JP2014-199308A, JP2014-085562A, JP2014-035351A, JP2008-081565A, JP2019-109512A, and JP2019-133154A.

A content of the pigment derivative is preferably 0.1 to 30 parts by mass with respect to 100 parts by mass of the pigment. The lower limit of this range is more preferably 0.25 parts by mass or more, still more preferably 0.5 parts by mass or more, particularly preferably 0.75 parts by mass or more, and most preferably 1 part by mass or more. In addition, the upper limit of this range is more preferably 25 parts by mass or less, still more preferably 20 parts by mass or less, and particularly preferably 15 parts by mass or less.

<<Curing Accelerator>>

For the purpose of promoting the reaction of polymerizable compounds or lowering a curing temperature, a curing accelerator may be added to the composition for a green pixel. Examples of the curing accelerator include a polyfunctional thiol compound having two or more mercapto groups in a molecule. The polyfunctional thiol compound may also be added for the purpose of improving stability, odor, resolution, developability, adhesiveness, or the like. In addition, as the curing accelerator, a methylol-based compound (for example, the compounds exemplified as a crosslinking agent in paragraph No. 0246 of JP2015-034963A), amines, phosphonium salts, amidine salts, and amide compounds (each of which is the curing agent described in, for example, paragraph No. 0186 of JP2013-041165A), base generators (for example, the ionic compounds described in JP2014-055114A), cyanate compounds (for example, the compounds described in paragraph No. 0071 of JP2012-150180A), alkoxysilane compounds (for example, the alkoxysilane compounds having an epoxy group, described in JP2011-253054A), onium salt compounds (for example, the compounds exemplified as an acid generator in paragraph No. 0216 of JP2015-034963A, and the compounds described in JP2009-180949A), or the like can also be used. A content of the curing accelerator in the total solid content of the composition for a green pixel is preferably 0.3 to 8.9 mass % and more preferably 0.8 to 6.4 mass %.

<<Silane Coupling Agent>>

The composition for a green pixel can contain a silane coupling agent. As the silane coupling agent, a silane compound having at least two kinds of functional groups having different reactivity in one molecule is preferable. The silane coupling agent is preferably a silane compound having at least one group selected from a vinyl group, an epoxy group, a styrene group, a methacryl group, an amino group, an isocyanurate group, a ureido group, a mercapto group, a sulfide group, or an isocyanate group, and an alkoxy group. Specific examples of the silane coupling agent include N-2-(aminoethyl)-3-aminopropyl methyldimethoxysilane (KBM-602, manufactured by Shin-Etsu Chemical Co., Ltd.), N-2-(aminoethyl)-3-aminopropyl trimethoxysilane (KBM-603, manufactured by Shin-Etsu Chemical Co., Ltd.), 3-aminopropyl trimethoxysilane (KBM-903, manufactured by Shin-Etsu Chemical Co., Ltd.), 3-aminopropyl triethoxysilane (KBE-903, manufactured by Shin-Etsu Chemical Co., Ltd.), 3-methacryloxypropyl trimethoxysilane (KBM-503, manufactured by Shin-Etsu Chemical Co., Ltd.), and 3-glycidoxypropyl trimethoxysilane (KBM-403, manufactured by Shin-Etsu Chemical Co., Ltd.). With regard to details of the silane coupling agent, reference can be made to the description in paragraph Nos. 0155 to 0158 of JP2013-254047A, the contents of which are incorporated herein by reference. A content of the silane coupling agent in the total solid content of the composition for a green pixel is preferably 0.001 to 20 mass %, more preferably 0.01 to 10 mass %, and particularly preferably 0.1 to 5 mass %. The composition for a green pixel may contain one kind or two or more kinds of the silane coupling agents. In a case of including two or more kinds thereof, the total amount thereof is preferably within the above-described range.

<<Polymerization Inhibitor>>

The composition for a green pixel can contain a polymerization inhibitor. Examples of the polymerization inhibitor include hydroquinone, p-methoxyphenol, di-t-butyl-p-cresol, pyrogallol, t-butyl catechol, benzoquinone, 4,4′-thiobis(3-methyl-6-t-butylphenol), 2,2′-methylenebis(4-methyl-6-t-butylphenol), and an N-nitrosophenylhydroxylamine salt (an ammonium salt, a cerous salt, or the like). A content of the polymerization inhibitor in the total solid content of the composition for a green pixel is preferably 0.0001 to 5 mass %. The composition for a green pixel may contain one kind or two or more kinds of the polymerization inhibitors. In a case of including two or more kinds thereof, the total amount thereof is preferably within the above-described range.

<<Ultraviolet absorber>>

The composition for a green pixel can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. With regard to details thereof, reference can be made to the description in paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Examples of a commercially available product of the ultraviolet absorber include UV-503 (manufactured by Daito Chemical Co., Ltd.). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraph Nos. 0049 to 0059 of JP6268967B can also be used. A content of the ultraviolet absorber in the total solid content of the composition for a green pixel is preferably 0.1 to 10 mass %, more preferably 0.1 to 5 mass %, and particularly preferably 0.1 to 3 mass %. In addition, the ultraviolet absorber may be used singly or in combination of two or more kinds thereof. In a case where two or more kinds thereof are used, it is preferable that the total amount thereof is within the above-described range.

<<Surfactant>>

The composition for a green pixel can contain a surfactant. As the surfactant, various surfactants such as a fluorine-based surfactant, a nonionic surfactant, a cationic surfactant, an anionic surfactant, and a silicon-based surfactant can be used. Examples of the surfactant include surfactants described in paragraph Nos. 0238 to 0245 of WO2015/166779A, the contents of which are incorporated herein by reference.

It is preferable that the surfactant is a fluorine-based surfactant. By including a fluorine-based surfactant in the composition, liquid characteristics (particularly, fluidity) are further improved, and liquid saving properties can be further improved. In addition, it is possible to form a film with a small thickness unevenness.

The fluorine content in the fluorine-based surfactant is suitably 3 to 40 mass %, and more preferably 5 to 30 mass % and particularly preferably 7% to 25 mass %. The fluorine-based surfactant in which the fluorine content is within the above-described range is effective from the viewpoint of the uniformity in the thickness of the coating film and liquid saving properties, and the solubility in the composition is also excellent.

Examples of the fluorine-based surfactant include surfactants described in paragraph Nos. 0060 to 0064 of JP2014-041318A (paragraph Nos 0060 to 0064 of the corresponding WO2014/017669A) and the like, and surfactants described in paragraph Nos 0117 to 0132 of JP2011-132503A, the contents of which are incorporated herein by reference. Examples of a commercially available product of the fluorine-based surfactant include: MEGAFACE F171, F172, F173, F176, F177, F141, F142, F143, F144, R30, F437, F475, F479, F482, F554, F780, EXP, and MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

In addition, it is also preferable that a polymer of a fluorine atom-containing vinyl ether compound having a fluorinated alkyl group or a fluorinated alkylene ether group, and a hydrophilic vinyl ether compound is used as the fluorine-based surfactant. Examples of such a fluorine-based surfactant include fluorine-based surfactants described in JP2016-216602A, the contents of which are incorporated herein by reference.

A block polymer can also be used as the fluorine-based surfactant. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraph Nos. 0016 to 0037 of JP2010-032698A, or the following compounds are also exemplified as the fluorine-based surfactant.

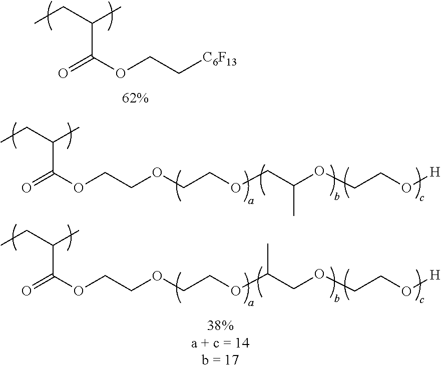

A weight-average molecular weight of the above-described compound is preferably 3000 to 50000 and, for example, 14000. In the compound, “%” representing the proportion of a repeating unit is mol %.

In addition, as the fluorine-based surfactant, a fluorine-containing polymer having an ethylenically unsaturated bond-containing group in the side chain can be used. Specific examples thereof include compounds described in paragraph Nos. 0050 to 0090 and paragraph Nos. 0289 to 0295 of JP2010-164965A, and MEGAFACE RS-101, RS-102, RS-718K, and RS-72-K manufactured by DIC Corporation. In addition, as the fluorine-based surfactant, compounds described in paragraph Nos. 0015 to 0158 of JP2015-117327A can also be used.

The content of the surfactant in the total solid content of the composition for a green pixel is preferably 0.001 mass % to 5.0 mass % and more preferably 0.005 to 3.0 mass %. The surfactant may be used singly or in combination of two or more kinds thereof. In a case of using two or more kinds thereof, the total amount thereof is preferably within the above-described range.

<<Other Additives>>

Various additives such as a filler, an adhesion promoter, an antioxidant, and an aggregation inhibitor can be blended into the composition for a green pixel, as desired. Examples of these additives include the additives described in paragraph Nos. 0155 and 0156 of JP2004-295116A, the contents of which are incorporated herein by reference. In addition, as the antioxidant, for example, a phenol compound, a phosphorus-based compound (for example, compounds described in paragraph No. 0042 of JP2011-090147A), a thioether compound, or the like can be used. Examples of a commercially available product thereof include ADK STAB series (AO-20, AO-30, AO-40, AO-50, AO-50F, AO-60, AO-60G, AO-80, AO-330, and the like) manufactured by ADEKA Corporation. In addition, as the antioxidant, polyfunctional hindered amine antioxidants described in WO2017/006600A, antioxidants described in WO2017/164024A, and antioxidants described in paragraph Nos. 0023 to 0048 of JP6268967B can also be used. The antioxidant may be used singly or in combination of two or more kinds thereof. In addition, optionally, the composition for a green pixel may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Specific examples of the potential antioxidant include compounds described in WO2014/021023A, WO2017/030005A, and JP2017-008219A. Examples of a commercially available product thereof include ADEKA ARKLS GPA-5001 (manufactured by ADEKA Corporation). In addition, the composition for a green pixel can contain sensitizers or light stabilizers described in paragraph No. 0078 of JP2004-295116A, thermal polymerization inhibitors described in paragraph No. 0081 of the same publication, or storage stabilizers described in paragraph No. 0242 of JP2018-091940A.

<Composition for Red Pixel>

<<Colorant>>

The composition for a red pixel includes one or more red colorants selected from C. I. Pigment Red 177, C. I. Pigment Red 264, and C. I. Pigment Red 269, and a yellow colorant other than C. I. Pigment Yellow 150.

Examples of the yellow colorant other than C. I. Pigment Yellow 150 (hereinafter, also referred to as a yellow colorant 1) include those described in the section of the red pixel described above, and at least one selected from an isoindoline compound or a quinophthalone compound is preferable, at least one selected from C. I. Pigment Yellow 139 or C. I. Pigment Yellow 185 is more preferable. In addition, the above-described yellow colorant 1 is preferably a yellow colorant different from the yellow colorant included in the composition for a green pixel.

The yellow colorant included in the composition for a red pixel may contain C. I. Pigment Yellow 150, but from the viewpoint that it is easier to suppress color transfer between the green pixel and the red pixel, it is preferable that the yellow colorant does not substantially contain C. I. Pigment Yellow 150. That is, it is preferable that the yellow colorant included in the composition for a red pixel is substantially only the yellow colorant 1.

The composition for a red pixel includes one or more red colorants (hereinafter, also referred to as a red colorant 1) selected from C. I. Pigment Red 177, C. I. Pigment Red 264, and C. I. Pigment Red 269. From the viewpoint of durability, the red colorant 1 is preferably Pigment Red 177 or 264.

The composition for a red pixel can contain a red colorant other than the above-described red colorant 1. Examples of other red colorants include those described in the section of the red pixel described above. A content of the above-described red colorant 1 in the red colorant included in the composition for a red pixel is preferably 50 to 100 mass %, more preferably 75 to 100 mass %, and still more preferably 90 to 100 mass %.

The composition for a red pixel may contain a colorant (hereinafter, also referred to as other colorants) other than the red colorant and the yellow colorant. Examples of the other colorants include a violet colorant and an orange colorant. Examples of the violet colorant include C. I. Pigment Violet 1, 19, 23, 27, 32, 37, 42, 60, and 61. Examples of the orange colorant include C. I. Pigment Orange 2, 5, 13, 16, 17:1, 31, 34, 36, 38, 43, 46, 48, 49, 51, 52, 55, 59, 60, 61, 62, 64, 71, and 73. A content of the other colorants is preferably 20 parts by mass or less, more preferably 12 parts by mass or less, and still more preferably 6 parts by mass or less with respect to 100 parts by mass of the total of the above-described red colorant 1 and the above-described yellow colorant 1.

A content of the colorant in the total solid content of the composition for a red pixel is preferably 15 mass % or more, more preferably 20 mass % or more, and still more preferably 25 mass % or more. The upper limit is preferably 60 mass % or less, more preferably 50 mass % or less, and still more preferably 40 mass % or less.

The composition for a red pixel preferably includes 5 to 100 parts by mass of the above-described yellow colorant 1, more preferably includes 10 to 90 parts by mass thereof, and still more preferably 20 to 80 parts by mass thereof with respect to 100 parts by mass of the above-described red colorant 1.

A total content of the above-described red colorant 1 and the above-described yellow colorant 1 in the total solid content of the composition for a red pixel is preferably 15 to 60 mass %, more preferably 22 to 52 mass %, and still more preferably 29 to 45 mass %.

<<Other Materials>>

The composition for a red pixel can contain the materials (polymerizable compound, photopolymerization initiator, resin, furyl group-containing compound, compound having an epoxy group, solvent, pigment derivative, curing accelerator, silane coupling agent, polymerization inhibitor, ultraviolet absorber, surfactant, and the like) described in the above description of the composition for a green pixel as a component other than the colorant. The details, preferred range, and content of these materials are synonymous with the above-described contents.

<Method for Manufacturing Color Filter>

The above-described color filter according to the embodiment of the present invention can be manufactured through a step of forming a green pixel using the composition for a green pixel, which includes Color Index Pigment Green 7 and Color Index Pigment Yellow 150, and a step of forming a red pixel using the composition for a red pixel, which includes one or more red colorants selected from Color Index Pigment Red 177, Color Index Pigment Red 264, and Color Index Pigment Red 269, and a yellow colorant other than Color Index Pigment Yellow 150.

In the step of forming a green pixel, it is preferable to form a green pixel by a photolithography method using the composition for a green pixel. In addition, in the step of forming a green pixel, it is preferable to form a red pixel by a photolithography method using the composition for a red pixel. The method for forming pixels by a photolithography method preferably includes a step of forming a composition layer by applying a composition for forming a pixel to a support, a step of exposing the composition layer in a patterned manner, and a step of developing the composition layer after exposure. A step of drying the composition layer (pre-baking step) and a step of heating the developed pixel (post-baking step) may be provided, as desired. By performing the above-described steps for each color, a color filter having a green pixel and a red pixel can be manufactured.

In addition, it is preferable that the step of forming a green pixel and the step of forming a red pixel are each performed at a temperature of 150° C. or lower. In the present specification, “performing the step of forming a green pixel at a temperature of 150° C. or lower” means that all steps of forming a green pixel using the composition for a green pixel are performed at a temperature of 150° C. or lower. For example, in a case where the post-baking step is provided in forming a green pixel by a photolithography method, it means that this post-baking step is also performed at a temperature of 150° C. or lower. The same applies to “performing the step of forming a red pixel at a temperature of 150° C. or lower”.

It is preferable that at least one selected from the composition for a green pixel or the composition for a red pixel contains the alkali-soluble resin, and it is more preferable that both the composition for a green pixel and the composition for a red pixel contain the alkali-soluble resin. According to this aspect, pattern formability in a photolithography method is excellent.

It is preferable that at least one selected from the composition for a green pixel or the composition for a red pixel contains the resin which has a repeating unit including a blocked isocyanate group, and it is more preferable that both the composition for a green pixel and the composition for a red pixel include the resin which has a repeating unit including a blocked isocyanate group. According to this aspect, more excellent low temperature curing properties can be obtained, and a sufficiently cured pixel can be formed even by heating at a relatively low temperature (for example, 150° C. or lower).

Hereinafter, a method of forming pixels by a photolithography method will be described.

In the step of forming a composition layer, the composition for forming a pixel according to the embodiment of the present invention is applied to a support to form a composition layer. The support is not particularly limited, and can be appropriately selected depending on applications. Examples thereof include a glass substrate and a silicon substrate. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, a base layer may be provided on the silicon substrate so as to improve adhesiveness to an upper layer, prevent the diffusion of materials, or planarize the surface of the substrate. A surface contact angle of the base layer is preferably 20° to 70° in a case of being measured with diiodomethane. In addition, the surface contact angle of the base layer is preferably 30° to 80° in a case of being measured with water. In a case where the surface contact angle of the base layer is within the above-described range, coating property of the composition for forming a pixel is good. The surface contact angle of the base layer can be adjusted by, for example, adding a surfactant.

As a method for applying the composition for forming a pixel, a known method can be used. Examples of the known method include: a drop casting method; a slit coating method; a spray method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprinting method. A method for applying the ink jet is not particularly limited, and examples thereof include a method described in “Extension of Use of Ink Jet—Infinite Possibilities in Patent-” (February, 2005, S. B. Research Co., Ltd.) (particularly pp. 115 to 133) and methods described in JP2003-262716A, JP2003-185831A, JP2003-261827A, JP2012-126830A, and JP2006-169325A. In addition, with regard to the method for applying the composition for forming a pixel reference can be made to the description in WO2017/030174A and WO2017/018419A, the contents of which are incorporated herein by reference.

The composition layer formed on the support may be dried (pre-baked). In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 to 3000 seconds. The pre-baking can be performed using a hot plate, an oven, or the like.

Next, the composition layer is exposed in a patterned manner (exposing step). For example, the composition layer can be exposed in a patterned manner using a stepper exposure device or a scanner exposure device through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the film formed from the composition according to the embodiment of the present invention may be irradiated with light continuously to expose the film formed from the composition according to the embodiment of the present invention, or the film formed from the composition according to the embodiment of the present invention may be irradiated with light in a pulse to expose the film formed from the composition according to the embodiment of the present invention (pulse exposure). The pulse exposure refers to an exposing method in which light irradiation and resting are repeatedly performed in a short cycle (for example, millisecond-level or less).

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

In addition, it is also preferable to irradiate with light (preferably i-rays) having a wavelength of more than 350 nm and 380 nm or less with an exposure amount of 1 J/cm² or more for exposure. By exposing in this way, the composition layer can be sufficiently cured.

Next, the composition layer after exposure is developed. That is, a non-exposed portion of the composition layer is removed by development to form a pattern (pixel). The non-exposed portion of the composition layer can be removed by development using a developer. Thus, the composition layer of the non-exposed portion in the exposing step is eluted into the developer, and as a result, only a photocured portion remains. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

Examples of the developer include an organic solvent and an alkali developer, and an alkali developer is preferably used. As the alkali developer, an aqueous alkaline solution (alkali developer) in which an alkaline agent is diluted with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo-[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the aqueous alkaline solution is preferably 0.001 to 10 mass % and more preferably 0.01 to 1 mass %. In addition, the developer may further contain a surfactant. From the viewpoint of transportation, storage, and the like, the developer may be first produced as a concentrated liquid and then diluted to a concentration required upon the use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the composition layer after development while rotating the support on which the composition layer after development is formed. In addition, it is preferable that the rinsing is performed by moving a nozzle jetting the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a curing treatment after development in order to complete curing.

In a case where the post-baking is performed, the heating temperature is preferably 100° C. to 150° C. The upper limit of the heating temperature is preferably 120° C. or lower. The heating time is preferably 1 minute or more, more preferably 5 minutes or more, and still more preferably 10 minutes or more. The upper limit thereof is not particularly limited, but from the viewpoint of productivity, 20 minutes or less is preferable. It is also preferable that the post-baking is performed in an atmosphere of an inert gas. According to this aspect, thermal polymerization can proceed with very high efficiency without being hindered by oxygen, and even in a case where a pixel is produced at a temperature of 150° C. or lower throughout the entire steps, it is possible to produce a pixel having high flatness and excellent characteristics such as solvent resistance. Examples of the inert gas include nitrogen gas, argon gas, and helium gas, and nitrogen gas is preferable. The oxygen concentration during post-baking is preferably 100 ppm or less.

In a case of performing the additional exposure treatment, it is preferable to irradiate with light having a wavelength of 254 to 350 nm for exposure. As a more preferred aspect, it is preferable that, in the step of exposing the composition layer (exposure before development) in a patterned manner, the composition layer is exposed by irradiating the composition layer with light having a wavelength of more than 350 nm and 380 nm or less (preferably light having a wavelength of 355 to 370 nm and more preferably i-rays), and in the additional exposure treatment (exposure after development), the composition layer after development is exposed by irradiating the composition layer with light having a wavelength of 254 to 350 nm (preferably light having a wavelength of 254 nm). According to this aspect, the composition layer can be moderately cured at the first exposure (exposure before development), and the entire composition layer can be cured almost completely at the next exposure (exposure after development). As a result, the composition layer can be sufficiently cured even under low temperature conditions, and it is possible to form a pixel having excellent characteristics such as solvent resistance, adhesiveness, and rectangularness. In a case where the exposure is performed in two stages as described above, in the composition for forming a pixel, it is preferable that a photopolymerization initiator including the photopolymerization initiator A1 having a light absorption coefficient of 1.0×10³ mL/g·cm or more at a wavelength of 365 nm in methanol and the photopolymerization initiator A2 having a light absorption coefficient of 1.0×10² mL/g·cm or less at a wavelength of 365 nm in methanol and having a light absorption coefficient of 1.0×10³ mL/g·cm or more at a wavelength of 254 nm in methanol is used as the photopolymerization initiator.

The exposure after development can be performed using, for example, an ultraviolet photoresist curing device. The light having a wavelength of 254 to 350 nm and other light (for example, i-rays) may irradiate from the ultraviolet photoresist curing device.

The exposure amount (irradiation amount) in the exposure after development is preferably 30 to 4000 mJ/cm² and more preferably 50 to 3500 mJ/cm². The difference between the wavelength of the light used for the exposure before development and the wavelength of the light used for the exposure after development is preferably 200 nm or less and more preferably 100 to 150 nm.

<Solid-State Imaging Element>

A solid-state imaging element according to an embodiment of the present invention includes the above-described color filter according to the embodiment of the present invention. The configuration of the solid-state imaging element is not particularly limited as long as the solid-state imaging element includes the color filter according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film; and have a color filter on the device-protective film. Further, the solid-state imaging element may also be configured, for example, such that it has a light collecting unit (for example, a microlens, which is the same hereinafter) on a device-protective film under a color filter (a side closer to the substrate), or has a light collecting unit on a color filter. An imaging device including the solid-state imaging element can also be used as a vehicle camera or a surveillance camera, in addition to a digital camera or electronic apparatus (mobile phones or the like) having an imaging function.

<Display Device>

A display device according to an embodiment of the present invention includes the above-described color filter according to the embodiment of the present invention. Examples of the display device include a liquid crystal display device or an organic electroluminescent display device. The definitions of display devices or the details of the respective display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

The organic electroluminescent display device may be an organic electroluminescent display device which has a light source composed of a white organic electroluminescent element. It is preferable that the white organic electroluminescent element has a tandem structure. The tandem structure of the organic electroluminescent element is described in, for example, JP2003-045676A, or pp. 326 to 328 of “Forefront of Organic EL Technology Development—Know-How Collection of High Brightness, High Precision, and Long Life” (Technical Information Institute, 2008). It is preferable that a spectrum of white light emitted from the organic EL element has high maximum emission peaks in a blue range (430 nm to 485 nm), a green range (530 nm to 580 nm), and a yellow range (580 nm to 620 nm). It is more preferable that the spectrum has a maximum emission peak in a red range (650 nm to 700 nm) in addition to the above-described emission peaks.

In addition, the organic electroluminescent display device may have a lens on the color filter. As a shape of the lens, various shapes derived by an optical system design can be taken, and examples thereof include a convex shape and a concave shape. For example, by taking a concave shape (concave lens), it is easy to improve light collecting property. In addition, the lens may be in direct contact with the color filter, or another layer such as an adhesion layer and a planarizing layer may be provided between the lens and the color filter. In addition, the lens can also be disposed and used in the manner described in WO2018/135189A.

### EXAMPLES

Hereinafter, the present invention will be described in more detail with reference to Examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below.

<Production of Colorant Solution>

Materials described in the tables below were uniformly stirred and mixed, and then using zirconia beads having a diameter of 1 mm, the mixture was dispersed for 5 hours with an Eiger motor mill (“Mini Model M-250 MKII” manufactured by Eiger Japan Co., Ltd.). Thereafter, the mixture was filtered with a filter having a pore size of 5 μm to produce a colorant solution.

TABLE 1

| | | Colorant solution | | | | | | | | |
|---|---|---|---|---|---|---|---|---|---|---|
| | | P-G1 | P-G2 | P-G3 | P-G4 | P-G5 | P-G6 | P-G7 | P-G8 | P-Gc1 |
| Green colorant | PG7 | 6.47 | 5.42 | 3.53 | 3.29 | 3.08 | 3.29 | 5.42 | 4.09 | |
| | PG36 | | | | 0.80 | 1.49 | | | | 4.09 |
| | PG58 | | | | | | 0.8 | | | |
| Yellow colorant | PY139 | | | | | | | 2.72 | | |
| | PY150 | 5.20 | 6.25 | 8.14 | 7.59 | 7.10 | 7.58 | 3.53 | 4.00 | |
| | PY185 | | | | | | | | 3.58 | 7.58 |

| | | | | | | | | | |
|---|---|---|---|---|---|---|---|---|---|
| Dispersant 1 | 6.09 | 6.09 | 6.09 | 6.09 | 6.09 | 6.09 | 6.09 | 6.09 | 6.09 |
| Dispersant 2 | 5.53 | 5.53 | 5.53 | 5.53 | 5.53 | 5.53 | 5.53 | 5.53 | 5.53 |
| Solvent 1 | 76.71 | 76.71 | 76.71 | 76.71 | 76.71 | 76.71 | 76.71 | 76.71 | 76.71 |

TABLE 2

| | | Colorant solution | | | | | | | | | |
|---|---|---|---|---|---|---|---|---|---|---|---|
| | | P-R1 | P-R2 | P-R3 | P-R4 | P-R5 | P-R6 | P-R7 | P-R8 | P-R9 | P-Rc1 |
| Red colorant | PR177 | 10.5 | 8.41 | | | 5.5 | 10.5 | 10.5 | 9.4 | 9.4 | |
| | PR264 | | | 10.5 | | 5 | | | | | |
| | PR269 | | | | 10.5 | | | | | | |
| | PR254 | | | | | | | | 0.6 | | 10.5 |
| Violet colorant | PV19 | | | | | | | | | 0.6 | |
| Yellow colorant | PY139 | 1.04 | 3.13 | 1.04 | 1.04 | 1.04 | | 0.52 | 1.54 | 1.54 | |
| | PY150 | | | | | | | | | | 1.04 |
| | PY185 | | | | | | 1.04 | 0.52 | | | |

| | | | | | | | | | | |
|---|---|---|---|---|---|---|---|---|---|---|
| Dispersant 2 | 7.66 | 7.66 | 7.66 | 7.66 | 7.66 | 7.66 | 7.66 | 7.66 | 7.66 | 7.66 |
| Dispersant 3 | 2.29 | 2.29 | 2.29 | 2.29 | 2.29 | 2.29 | 2.29 | 2.29 | 2.29 | 2.29 |
| Pigment derivative 1 | 2.69 | 2.69 | 2.69 | 2.69 | 2.69 | 2.69 | 2.69 | 2.69 | 2.69 | 2.69 |
| Solvent 2 | 75.82 | 75.82 | 75.82 | 75.82 | 75.82 | 75.82 | 75.82 | 75.82 | 75.82 | 75.82 |

Details of the materials indicated by the abbreviations in the above tables are as follows.

(Green Colorant)

PG7: C. I. Pigment Green 7

PG36: C. I. Pigment Green 36

PG58: C. I. Pigment Green 58

(Yellow Colorant)

PY139: C. I. Pigment Yellow 139

PY150: C. I. Pigment Yellow 150

PY185: C. I. Pigment Yellow 185

(Red Colorant)

PR177: C. I. Pigment Red 177

PR264: C. I. Pigment Red 264

PR269: C. I. Pigment Red 269

PR254: C. I. Pigment Red 254

(Violet Colorant)

PV19: C. I. Pigment Violet 19

(Dispersant)

Dispersant 1: Disperbyk-2001 (manufactured by BYK Chemie, concentration of solid contents: 46 mass %)

Dispersant 2: resin solution having a concentration of solid contents of 20 mass %, which is produced by the following method

90.0 parts by mass of cyclohexanone was charged into a reaction container equipped with a stirrer, a thermometer, a dropping device, a reflux condenser, and a gas introduction tube, and was heated to 60° C. while injecting nitrogen gas into the container, and at the same temperature, a mixture of 20.0 parts by mass of methacrylic acid, 10.0 parts by mass of methyl methacrylate, 55.0 parts by mass of n-butyl methacrylate, 15 parts by mass of benzyl methacrylate, and 2.5 parts by mass of 2,2′-azobisisobutyronitrile was added dropwise thereto over 2 hours to perform a polymerization reaction. After the dropwise addition, the mixture was further reacted at 60° C. for 1 hour, 0.5 parts by mass of 2,2′-azobisisobutyronitrile dissolved in 10.0 parts by mass of propylene glycol monomethyl ether acetate (PGMEA) was added thereto, and then stirring was continued at the same temperature for 3 hours to obtain a copolymer. After cooling to room temperature, the reactant was diluted with cyclohexanone to obtain a resin solution having a concentration of solid contents of 20 mass %. The weight-average molecular weight of the resin was 30000.

Dispersant 3: Solsperse 20000 (manufactured by Nippon Lubrizol Corporation)

(Pigment Derivative)

Pigment derivative 1: compound having the following structure

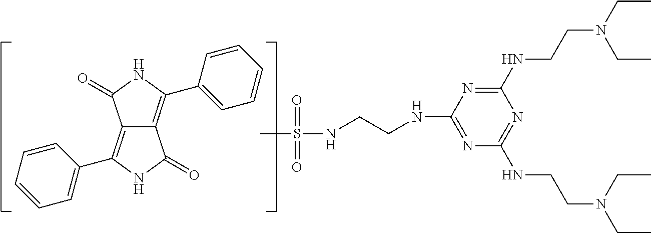

(Solvent)

Solvent 1: propylene glycol monomethyl ether acetate (PGMEA)

Solvent 2: cyclohexanone

<Production of Composition for Green Pixel and Composition for Red Pixel>

Materials shown in the tables below were mixed and stirred, and then using a nylon filter (manufactured by Nihon Pall Corporation) having a pore size of 0.45 the mixture was filtered to produce a composition for a green pixel and a composition for a red pixel, respectively. Numerical values described in the column of part by mass of the resin are values expressed in terms of solid contents.

TABLE 3

| | | | Photopolymerization | | | | Polymerizable | | | |
|---|---|---|---|---|---|---|---|---|---|---|
| | Colorant solution | | initiator | | Resin | | compound | | Solvent | |
| Composition | | Content | | Content | | Content | | Content | | Content |
| for green | | (part by | | (part by | | (part by | | (part by | | (part by |
| pixel | Type | mass) | Type | mass) | Type | mass) | Type | mass) | Type | mass) |
| R-G1 | P-G1 | 65 | Initiator 1 | 2 | Resin 1 | 5.5 | Monomer 1 | 2.6 | Solvent 1 | 19.4 |
| R-G2 | P-G2 | 65 | Initiator 1 | 2 | Resin 1 | 5.5 | Monomer 1 | 2.6 | Solvent 1 | 19.4 |
| R-G3 | P-G3 | 65 | Initiator 1 | 2 | Resin 1 | 5.5 | Monomer 1 | 2.6 | Solvent 1 | 19.4 |
| R-G4 | P-G4 | 65 | Initiator 1 | 2 | Resin 1 | 5.5 | Monomer 1 | 2.6 | Solvent 1 | 19.4 |
| R-G5 | P-G5 | 65 | Initiator 1 | 2 | Resin 1 | 5.5 | Monomer 1 | 2.6 | Solvent 1 | 19.4 |
| R-G6 | P-G6 | 65 | Initiator 1 | 2 | Resin 1 | 5.5 | Monomer 1 | 2.6 | Solvent 1 | 19.4 |
| R-G7 | P-G7 | 65 | Initiator 1 | 2 | Resin 1 | 5.5 | Monomer 1 | 2.6 | Solvent 1 | 19.4 |
| R-G8 | P-G8 | 65 | Initiator 1 | 2 | Resin 1 | 5.5 | Monomer 1 | 2.6 | Solvent 1 | 19.4 |
| R-G9 | P-G1 | 65 | Initiator 1 | 2 | Resin 1 | 5.5 | Monomer 1 | 2.6 | Solvent 1 | 9.7 |
| | | | | | | | | | | 9.7 |
| R-G10 | P-G1 | 65 | Initiator 1 | 2 | Resin 1 | 2.75 | Monomer 1 | 2.6 | Solvent 1 | 19.4 |
| | | | | | Resin 2 | 2.75 | | | | |
| R-G11 | P-G1 | 65 | Initiator 1 | 2 | Resin 1 | 5.5 | Monomer 1 | 1.3 | Solvent 1 | 19.4 |
| | | | | | | | Monomer 2 | 1.3 | | |
| R-G12 | P-G1 | 65 | Initiator 1 | 2 | Resin 1 | 5.5 | Monomer 1 | 2.6 | Solvent 1 | 19.4 |
| R-G13 | P-G1 | 65 | Initiator 1 | 1 | Resin 1 | 5.5 | Monomer 1 | 2.6 | Solvent 1 | 19.4 |
| | | | Initiator 4 | 1 | | | | | | |
| R-G14 | P-G5 | 65 | Initiator 1 | 1 | Resin 1 | 5.5 | Monomer 1 | 2.6 | Solvent 1 | 19.4 |
| | | | Initiator 4 | 1 | | | | | | |
| R-Gc1 | P-Gc1 | 65 | Initiator 1 | 2 | Resin 1 | 5.5 | Monomer 1 | 2.6 | Solvent 1 | 19.4 |

TABLE 4

| | | | Photopolymerization | | | | Polymerizable | | | |
|---|---|---|---|---|---|---|---|---|---|---|
| | Colorant solution | | initiator | | Resin | | compound | | Solvent | |
| | | Content | | Content | | Content | | Content | | Content |
| Composition | | (part by | | (part by | | (part by | | (part by | | (part by |
| for red pixel | Type | mass) | Type | mass) | Type | mass) | Type | mass) | Type | mass) |
| R-R1 | P-R1 | 65 | Initiator 1 | 2 | Resin 1 | 5.5 | Monomer 1 | 2.6 | Solvent 1 | 19.4 |
| R-R2 | P-R2 | 65 | Initiator 1 | 2 | Resin 1 | 5.5 | Monomer 1 | 2.6 | Solvent 1 | 19.4 |
| R-R3 | P-R3 | 65 | Initiator 1 | 2 | Resin 1 | 5.5 | Monomer 1 | 2.6 | Solvent 1 | 19.4 |
| R-R4 | P-R4 | 65 | Initiator 1 | 2 | Resin 1 | 5.5 | Monomer 1 | 2.6 | Solvent 1 | 19.4 |
| R-R5 | P-R5 | 65 | Initiator 1 | 2 | Resin 1 | 5.5 | Monomer 1 | 2.6 | Solvent 1 | 19.4 |
| R-R6 | P-R6 | 65 | Initiator 1 | 2 | Resin 1 | 5.5 | Monomer 1 | 2.6 | Solvent 1 | 19.4 |
| R-R7 | P-R7 | 65 | Initiator 1 | 2 | Resin 1 | 5.5 | Monomer 1 | 2.6 | Solvent 1 | 19.4 |
| R-R8 | P-R8 | 65 | Initiator 1 | 2 | Resin 1 | 5.5 | Monomer 1 | 2.6 | Solvent 1 | 19.4 |
| R-R9 | P-R9 | 65 | Initiator 1 | 2 | Resin 1 | 5.5 | Monomer 1 | 2.6 | Solvent 1 | 19.4 |
| R-R10 | P-R1 | 65 | Initiator 1 | 2 | Resin 1 | 5.5 | Monomer 1 | 2.6 | Solvent 1 | 9.7 |
| | | | | | | | | | Solvent 3 | 9.7 |
| R-R11 | P-R1 | 65 | Initiator 1 | 2 | Resin 1 | 2.75 | Monomer 1 | 2.6 | Solvent 1 | 19.4 |
| | | | | | Resin 2 | 2.75 | | | | |
| R-R12 | P-R1 | 65 | Initiator 1 | 2 | Resin 2 | 5.5 | Monomer 1 | 1.3 | Solvent 1 | 19.4 |
| | | | | | | | Monomer 2 | 1.3 | | |
| R-R13 | P-R1 | 65 | Initiator 1 | 2 | Resin 3 | 5.5 | Monomer 1 | 2.6 | Solvent 1 | 19.4 |
| R-R14 | P-R1 | 65 | Initiator 1 | 1 | Resin 1 | 5.5 | Monomer 1 | 2.6 | Solvent 1 | 19.4 |
| | | | Initiator 4 | 1 | | | | | | |
| R-R15 | P-R3 | 65 | Initiator 1 | 1 | Resin 1 | 5.5 | Monomer 1 | 2.6 | Solvent 1 | 19.4 |
| | | | Initiator 4 | 1 | | | | | | |
| R-R16 | P-R8 | 65 | Initiator 1 | 1 | Resin 1 | 5.5 | Monomer 1 | 2.6 | Solvent 1 | 19.4 |
| | | | Initiator 4 | 1 | | | | | | |
| R-R17 | P-R9 | 65 | Initiator 1 | 1 | Resin 1 | 5.5 | Monomer 1 | 2.6 | Solvent 1 | 19.4 |
| | | | Initiator 4 | 1 | | | | | | |
| R-Rc1 | P-Rc1 | 65 | Initiator 1 | 2 | Resin 1 | 5.5 | Monomer 1 | 2.6 | Solvent 1 | 19.4 |

In the above tables, the details of the materials indicated by abbreviations are as follows.

(Colorant Solution)

P-G1 to P-G8, P-Gc1, P-R1 to P-R9, P-Rc1: colorant solutions P-G1 to P-G8, P-Gc1, P-R1 to P-R9, and P-Rc1 described above

(Photopolymerization Initiator)

Initiator 1: compound having the following structure

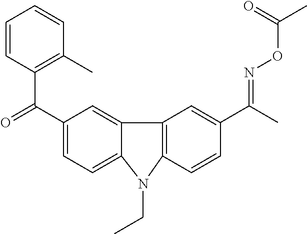 [SMILES: CCn1c2ccc(C(=O)c3ccccc3C)cc2c2cc(/C(C)=N/OC(C)=O)ccc21]

Initiator 4: compound having the following structure

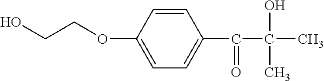 [SMILES: CC(C)(O)C(=O)c1ccc(OCCO)cc1]

(Resin)

Resin 1: resin synthesized by the following method

70.0 parts by mass of cyclohexanone was charged into a separable four-neck flask equipped with a thermometer, a cooling pipe, a nitrogen gas introduction pipe, a dropping tube, and a stirrer, and was heated to 80° C., and after replacing the inside of the flask with nitrogen, from the dropping tube, a mixture of 13.3 parts by mass of n-butyl methacrylate, 4.6 parts by mass of 2-hydroxyethyl methacrylate, 4.3 parts by mass of methacrylic acid, 7.4 parts by mass of para-cumylphenol ethyleneoxide-modified acrylate (ARONIX M110 manufactured by TOAGOSEI CO., LTD.), and 0.4 parts by mass of 2,2′-azobisisobutyronitrile was added dropwise thereto over 2 hours. After the dropwise addition, the reaction was continued for another 3 hours to obtain a 30 mass % solution of a resin 1 (Mw=26000).

Resin 2: resin synthesized by the following method 90.0 parts by mass of PGMEA was charged into a reaction container equipped with a stirrer, a thermometer, a dropping device, a reflux condenser, and a gas introduction tube, and was heated to 60° C. while injecting nitrogen gas into the container, and at the same temperature, a mixture of 10.0 parts by mass of methacrylic acid, 45.0 parts by mass of methyl methacrylate, 45.0 parts by mass of n-butyl methacrylate, and 2.5 parts by mass of 2,2′-azobisisobutyronitrile was added dropwise thereto over 2 hours to perform a polymerization reaction. After the dropwise addition, the mixture was further reacted at 60° C. for 1 hour, 0.5 parts by mass of 2,2′-azobisisobutyronitrile dissolved in 10.0 parts by mass of PGMEA was added thereto, and then stirring was continued at the same temperature for 3 hours to obtain a copolymer. After cooling to room temperature, the copolymer was diluted with PGMEA to obtain a solution of a resin 2 which included an alkali-soluble functional group and had a non-volatile content of 20 mass %. The weight-average molecular weight of the resin 2 was 27000.

Resin 3: resin having the following structure (resin which has a repeating unit including a blocked isocyanate group; the numerical value described together with the main chain indicates a mass ratio)

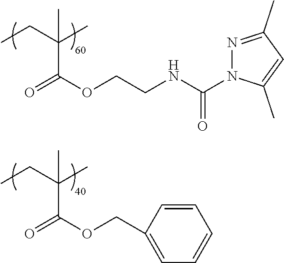

(Polymerizable Compound)

Monomer 1: ARONIX M-402 (manufactured by TOAGOSEI CO., LTD.; mixture of dipentaerythritol hexaacrylate and dipentaerythritol pentaacrylate)

Monomer 2: compound having the following structure (a+b+c=3)

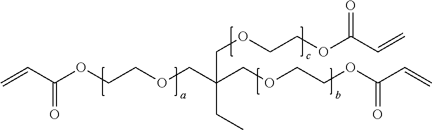

(Solvent)

Solvent 1: propylene glycol monomethyl ether acetate (PGMEA)

Solvent 3: propylene glycol monomethyl ether (PGME)

<Manufacturing of Color Filter>

### Example 1

To an 8-inch (203.2 mm) glass wafer with an undercoat layer, the composition R-G1 for a green pixel was applied with a spin coater so that a finished film thickness after drying was 2.0 and dried on a hot plate at 100° C. for 2 minutes. Thereafter, using an ultra-high pressure mercury lamp, exposure was performed through a mask having a 5.0 μm square pattern under conditions of an exposure illuminance of 20 mW/cm² and an exposure amount of 1 J/cm². Next, puddle development was performed at 23° C. for 60 seconds using a 0.3 mass % of tetramethylammonium hydroxide (TMAH) aqueous solution. Next, the composition layer was rinsed by spin showering and was cleaned with pure water. Next, a green colored pattern (green pixel) was formed by heating at 200° C. for 5 minutes using a hot plate.

Next, to the glass wafer on which the green pixel had been formed, the composition R-R1 for a red pixel was applied with a spin coater so that a finished film thickness after drying was 2.0 and dried on a hot plate at 100° C. for 2 minutes. Thereafter, using an ultra-high pressure mercury lamp, exposure was performed through a mask having a 5.0 μm square pattern under conditions of an exposure illuminance of 20 mW/cm² and an exposure amount of 1 J/cm². Next, puddle development was performed at 23° C. for 60 seconds using a 0.3 mass % of tetramethylammonium hydroxide (TMAH) aqueous solution. Next, the composition layer was rinsed by spin showering and was cleaned with pure water. Next, by heating the composition layer at 200° C. for 5 minutes using a hot plate, a red colored pattern (red pixel) was formed in a missing portion of the green pixel, thereby manufacturing a color filter of Example 1.

### Examples 2 to 77 and 79 to 83, Comparative Examples 1 and 2

A color filter was manufactured in the same manner as in Example 1, except that the composition for a green pixel and the composition for a red pixel were changed to the types shown in the tables below.

### Example 78

To an 8-inch (203.2 mm) glass wafer with an undercoat layer, the composition R-G13 for a green pixel was applied with a spin coater so that a finished film thickness after drying was 2.0 and dried on a hot plate at 100° C. for 2 minutes. Thereafter, using an ultra-high pressure mercury lamp, exposure was performed through a mask having a 5.0 μm square pattern under conditions of an exposure illuminance of 20 mW/cm² and an exposure amount of 1 J/cm². Next, puddle development was performed at 23° C. for 60 seconds using a 0.3 mass % of tetramethylammonium hydroxide (TMAH) aqueous solution. Next, the composition layer was rinsed by spin showering and was cleaned with pure water. Next, using an ultraviolet photoresist curing device (UMA-802-HC-552, manufactured by USHIO INC.), the composition layer was subjected to an exposure with an exposure amount of 3000 mJ/cm² to form a green colored pattern (green pixel).

Next, to the glass wafer on which the green pixel had been formed, the composition R-R14 for a red pixel was applied with a spin coater so that a finished film thickness after drying was 2.0 and dried on a hot plate at 100° C. for 2 minutes. Thereafter, using an ultra-high pressure mercury lamp, exposure was performed through a mask having a 5.0 μm square pattern under conditions of an exposure illuminance of 20 mW/cm² and an exposure amount of 1 J/cm². Next, puddle development was performed at 23° C. for 60 seconds using a 0.3 mass % of tetramethylammonium hydroxide (TMAH) aqueous solution. Next, the composition layer was rinsed by spin showering and was cleaned with pure water. Next, using an ultraviolet photoresist curing device (UMA-802-HC-552, manufactured by USHIO INC.), the composition layer was subjected to an exposure with an exposure amount of 3000 mJ/cm² to form a red colored pattern (red pixel) in a missing portion of the green pixel, thereby manufacturing a color filter of Example 78.

### Examples 84 and 85

To an 8-inch (203.2 mm) glass wafer with an undercoat layer, the composition R-G1 for a green pixel was applied with a spin coater so that a finished film thickness after drying was 2.0 and dried on a hot plate at 100° C. for 2 minutes. Thereafter, using an ultra-high pressure mercury lamp, exposure was performed through a mask having a 5.0 μm square pattern under conditions of an exposure illuminance of 20 mW/cm² and an exposure amount of 1 J/cm². Next, puddle development was performed at 23° C. for 60 seconds using a 0.3 mass % of tetramethylammonium hydroxide (TMAH) aqueous solution. Next, the composition layer was rinsed by spin showering and was cleaned with pure water. Next, a green colored pattern (green pixel) was formed by heating at 100° C. for 20 minutes using a hot plate.

Next, to the glass wafer on which the green pixel had been formed, the composition R-R1 for a red pixel was applied with a spin coater so that a finished film thickness after drying was 2.0 and dried on a hot plate at 100° C. for 2 minutes. Thereafter, using an ultra-high pressure mercury lamp, exposure was performed through a mask having a 5.0 μm square pattern under conditions of an exposure illuminance of 20 mW/cm² and an exposure amount of 1 J/cm². Next, puddle development was performed at 23° C. for 60 seconds using a 0.3 mass % of tetramethylammonium hydroxide (TMAH) aqueous solution. Next, the composition layer was rinsed by spin showering and was cleaned with pure water. Next, by heating the composition layer at 100° C. for 20 minutes using a hot plate, a red colored pattern (red pixel) was formed in a missing portion of the green pixel, thereby manufacturing a color filter of Example 84 and 85.

### Example 86

To an 8-inch (203.2 mm) glass wafer with an undercoat layer, the composition R-G1 for a green pixel was applied with a spin coater so that a finished film thickness after drying was 2.0 μm, and dried on a hot plate at 100° C. for 2 minutes. Thereafter, using an ultra-high pressure mercury lamp, exposure was performed through a mask having a 5.0 μm square pattern under conditions of an exposure illuminance of 20 mW/cm² and an exposure amount of 1 J/cm². Next, puddle development was performed at 23° C. for 60 seconds using a 0.3 mass % of tetramethylammonium hydroxide (TMAH) aqueous solution. Next, the composition layer was rinsed by spin showering and was cleaned with pure water. Next, using an i-ray stepper exposure device FPA-3000 i5+ (manufactured by Canon Inc.), exposure was performed with light having an exposure amount of 1500 mJ/cm² to form a green colored pattern (green pixel).

Next, to the glass wafer on which the green pixel had been formed, the composition R-R1 for a red pixel was applied with a spin coater so that a finished film thickness after drying was 2.0 μm, and dried on a hot plate at 100° C. for 2 minutes. Thereafter, using an ultra-high pressure mercury lamp, exposure was performed through a mask having a 5.0 μm square pattern under conditions of an exposure illuminance of 20 mW/cm² and an exposure amount of 1 J/cm². Next, puddle development was performed at 23° C. for 60 seconds using a 0.3 mass % of tetramethylammonium hydroxide (TMAH) aqueous solution. Next, the composition layer was rinsed by spin showering and was cleaned with pure water. Next, using an i-ray stepper exposure device FPA-3000 i5+ (manufactured by Canon Inc.), exposure was performed with light having an exposure amount of 1500 mJ/cm² to form a red colored pattern (red pixel) in a missing portion of the green pixel, thereby manufacturing a color filter of Example 86.

<Evaluation>

(Color Separation 1)

Using an ultraviolet-visible-near infrared spectrophotometer UV3600 (manufactured by Shimadzu Corporation), an absorbance of light in a wavelength range of 300 to 800 nm was measured for the green pixel and the red pixel of the obtained color filter. In light having a wavelength range of 400 to 700 nm, a difference (ΔT1=λr1−λg1) between a wavelength λg1 of light on a short wavelength side where a transmittance of the green pixel was 5% and a wavelength λr1 of light on a long wavelength side where a transmittance of the red pixel was 5% was determined and evaluated according to the following standard. In the following evaluation standard, S, A, and B are practical.

S: ΔT1 was 112 nm or more and 115 nm or less.

A: ΔT1 was 105 nm or more and less than 112 nm.

B: ΔT1 was 98 nm or more and less than 105 nm.

C: ΔT1 was 91 nm or more and less than 98 nm.

D: ΔT1 was less than 91 nm or more than 115 nm.

(Color Separation 2)

Using an ultraviolet-visible-near infrared spectrophotometer UV3600 (manufactured by Shimadzu Corporation), an absorbance of light in a wavelength range of 300 to 800 nm was measured for the green pixel and the red pixel of the obtained color filter. In light having a wavelength range of 400 to 700 nm, a difference (ΔT2=λr2−λg2) between a wavelength of light on a long wavelength side where a transmittance of the green pixel was 30% and a wavelength of light on a long wavelength side where a transmittance of the red pixel was 30% was determined and evaluated according to the following standard. In the following evaluation standard, S, A, and B are practical.

S: ΔT2 was 30 nm or more and 33 nm or less.

A: ΔT2 was 20 nm or more and less than 30 nm.

B: ΔT2 was 10 nm or more and less than 20 nm.

C: ΔT2 was 0 nm or more and less than 10 nm.

D: ΔT2 was less than 0 nm or more than 33 nm.

<Color Transfer>

A transmittance (spectrum 1) of the green pixel of the obtained color filter in a wavelength range of 400 to 700 nm was measured by using a spectrometer system (LVmicro V, manufactured by Lambda Vision Inc.).

Next, after the color filter was stored in a high temperature chamber set at 100° C. for 1000 hours, a transmittance (spectrum 2) of the green pixel in a wavelength range of 400 to 700 nm was measured by using a spectrometer system (LVmicro V, manufactured by Lambda Vision Inc.).

The maximum value of variation of transmittance was determined by using the spectrums 1 and 2 of the green pixel, and a change in transmittance was evaluated according to the following standard.

The measurement of transmittance was performed 5 times for each sample, and the average value of the 3 times result except the maximum value and the minimum value was adopted. Furthermore, the maximum value of variation of transmittance means a variation of transmittance of the green pixel in a wavelength which has the largest variation of transmittance in a range of 400 to 700 nm before and after heating.

S: maximum value of variation of transmittance was less than 0.2%.

A: maximum value of variation of transmittance was 0.2% or more and less than 0.6%.

B: maximum value of variation of transmittance was 0.6% or more and less than 1.0%

C: maximum value of variation of transmittance was 1.0% or more and less than 1.4%

D: maximum value of variation of transmittance was 1.4% or more.

TABLE 5

| | Pixel | | | | |
|---|---|---|---|---|---|
| | Composition | Composition | Color | Color | Color |
| | for green pixel | for red pixel | separation 1 | separation 2 | transfer |
| Example 1 | R-G1 | R-R1 | S | S | S |
| Example 2 | | R-R2 | A | A | A |
| Example 3 | | R-R3 | S | S | S |
| Example 4 | | R-R4 | S | S | S |
| Example 5 | | R-R5 | A | S | S |
| Example 6 | | R-R6 | A | S | A |
| Example 7 | | R-R7 | A | S | A |
| Example 8 | | R-R8 | A | A | A |
| Example 9 | | R-R9 | S | S | S |
| Example 10 | R-G2 | R-R1 | A | A | S |
| Example 11 | | R-R2 | A | A | A |
| Example 12 | | R-R3 | S | A | A |
| Example 13 | | R-R4 | S | A | A |
| Example 14 | | R-R5 | A | A | A |
| Example 15 | | R-R6 | A | A | B |
| Example 16 | | R-R7 | A | A | A |
| Example 17 | | R-R8 | A | A | A |
| Example 18 | | R-R9 | A | A | A |
| Example 19 | R-G3 | R-R1 | A | B | A |
| Example 20 | | R-R2 | A | B | B |
| Example 21 | | R-R3 | A | B | A |
| Example 22 | | R-R4 | A | B | A |
| Example 23 | | R-R5 | A | B | A |
| Example 24 | | R-R6 | A | B | A |
| Example 25 | | R-R7 | A | B | S |
| Example 26 | | R-R8 | A | B | A |
| Example 27 | | R-R9 | A | B | A |
| Example 28 | R-G4 | R-R1 | A | B | S |
| Example 29 | | R-R2 | A | B | A |
| Example 30 | | R-R3 | A | B | A |
| Example 31 | | R-R4 | A | B | A |
| Example 32 | | R-R5 | A | B | A |
| Example 33 | | R-R6 | A | B | A |
| Example 34 | | R-R7 | A | B | A |
| Example 35 | | R-R8 | A | B | A |
| Example 36 | | R-R9 | A | B | A |
| Example 37 | R-G5 | R-R1 | A | B | A |
| Example 38 | | R-R2 | A | B | S |
| Example 39 | | R-R3 | A | B | A |
| Example 40 | | R-R4 | A | B | A |
| Example 41 | | R-R5 | A | B | A |
| Example 42 | | R-R6 | A | B | A |
| Example 43 | | R-R7 | A | B | A |
| Example 44 | | R-R8 | A | B | A |
| Example 45 | | R-R9 | A | B | S |

TABLE 6

| | Pixel | | | | |
|---|---|---|---|---|---|
| | Composition | Composition | Color | Color | Color |
| | for green pixel | for red pixel | separation 1 | separation 2 | transfer |
| Example 46 | R-G6 | R-R1 | A | B | A |
| Example 47 | | R-R2 | A | B | A |
| Example 48 | | R-R3 | A | B | S |
| Example 49 | | R-R4 | A | B | A |
| Example 50 | | R-R5 | A | B | A |
| Example 51 | | R-R6 | A | B | S |
| Example 52 | | R-R7 | A | B | B |
| Example 53 | | R-R8 | A | B | A |
| Example 54 | | R-R9 | A | B | A |
| Example 55 | R-G7 | R-R1 | B | A | B |
| Example 56 | | R-R2 | B | A | B |
| Example 57 | | R-R3 | A | A | B |
| Example 58 | | R-R4 | A | A | B |
| Example 59 | | R-R5 | B | A | B |
| Example 60 | | R-R6 | B | A | S |
| Example 61 | | R-R7 | B | A | B |
| Example 62 | | R-R8 | B | A | B |
| Example 63 | | R-R9 | B | A | B |
| Example 64 | R-G8 | R-R1 | B | A | A |
| Example 65 | | R-R2 | B | A | A |
| Example 66 | | R-R3 | B | A | A |
| Example 67 | | R-R4 | B | A | A |
| Example 68 | | R-R5 | B | A | A |
| Example 69 | | R-R6 | B | A | B |
| Example 70 | | R-R7 | B | A | B |
| Example 71 | | R-R8 | B | A | A |
| Example 72 | | R-R9 | B | A | A |
| Example 73 | R-G9 | R-R10 | S | S | A |
| Example 74 | R-G10 | R-R11 | S | S | A |
| Example 75 | R-G11 | R-R12 | S | S | A |
| Example 76 | R-G12 | R-R13 | S | S | B |
| Example 77 | R-G13 | R-R14 | S | S | S |
| Example 78 | | R-R14 | S | S | S |
| Example 79 | | R-R15 | A | A | A |
| Example 80 | | R-R16 | S | S | S |
| Example 81 | R-G14 | R-R14 | A | B | A |
| Example 82 | | R-R15 | A | B | A |
| Example 83 | | R-R16 | A | B | S |
| Example 84 | R-G1 | R-R1 | S | S | B |
| Example 85 | R-G12 | R-R13 | S | S | A |
| Example 86 | R-G1 | R-R1 | S | S | A |
| Comparative | R-Gc1 | R-Rc1 | C | D | C |
| Example 1 | | | | | |
| Comparative | R-G1 | R-Rc1 | A | B | D |
| Example 2 | | | | | |

As shown in the above tables, the color filters of Examples were a color filter in which color mixing due to color transfer was suppressed.

### Example 1001

A silicon wafer was coated with a composition for a green pixel by a spin coating method so that a film thickness after film formation was 1.0 μm. Next, the composition was heated using a hot plate at 100° C. for 2 minutes. Next, using an i-ray stepper exposure device FPA-3000 i5+ (manufactured by Canon Inc.), exposure was performed at an exposure amout of 1000 mJ/cm² through a mask having a dot pattern of 2 μm square. Next, puddle development was performed at 23° C. for 60 seconds using a 0.3 mass % of tetramethylammonium hydroxide (TMAH) aqueous solution. Next, the composition layer was rinsed by spin showering and was cleaned with pure water. Next, a green colored pattern (green pixel) was formed by heating at 200° C. for 5 minutes using a hot plate. In the same manner, a composition for a red pixel and a composition for a blue pixel were sequentially patterned to form a red colored pattern (red pixel) and a blue colored pattern (blue pixel), respectively, thereby manufacturing a color filter. As the composition for a green pixel, the composition R-G1 for a green pixel was used. As the composition for a red pixel, the composition R-R1 for a red pixel was used. The composition for a blue pixel will be described later.

The obtained color filter was incorporated into an organic electroluminescent display device according to a known method. This organic electroluminescent display device had a suitable image recognition ability.

[Composition for Blue Pixel]

A mixture having the following composition was stirred and mixed so as to be uniform, and then filtered through a 1.0 μm filter to produce the composition for a blue pixel.

Pigment dispersion liquid DB-1 . . . 10.4 parts by mass

Pigment dispersion liquid DV-1 . . . 6.1 parts by mass

Resin solution 11 . . . 24.2 parts by mass

Polymerizable compound (ARONIX M-402, manufactured by TOAGOSEI CO., LTD.) . . . 0.7 parts by mass

Photopolymerization initiator (Irgacure OXE02, manufactured by BASF) . . . 0.3 parts by mass

PGMEA . . . 44.2 parts by mass

The pigment dispersion liquid DB-1 was prepared by the following method.

11.0 parts by mass of C. I. Pigment Blue 15:6, 21.5 parts by mass of a resin solution 11, 1 part by mass of a dispersant (manufactured by BASF, EFKA4300), and 66.5 parts by mass of PGMEA were mixed, and then using zirconia beads having a diameter of 1 mm, the mixture was dispersed for 5 hours with an Eiger mill (“Mini Model M-250 MKII” manufactured by Eiger Japan Co., Ltd.). Thereafter, the mixture was filtered through a filter having a pore size of 5 μm to prepare the pigment dispersion liquid DB-1.

The pigment dispersion liquid DV-1 was prepared by the following method.

11.0 parts by mass of C. I. Pigment Violet 23, 21.5 parts by mass of a resin solution 11, 1 part by mass of a dispersant (manufactured by BASF, EFKA4300), and 66.5 parts by mass of PGMEA were mixed, and then using zirconia beads having a diameter of 1 mm, the mixture was dispersed for 5 hours with an Eiger mill (“Mini Model M-250 MKII” manufactured by Eiger Japan Co., Ltd.). Thereafter, the mixture was filtered through a filter having a pore size of 5 μm to prepare the pigment dispersion liquid DV-1.

The resin solution 11 was prepared by the following method.

207 parts by mass of PGMEA was charged into a reaction container in which a separable four-neck flask was equipped with a thermometer, a cooling pipe, a nitrogen gas introduction pipe, a dropping tube, and a stirrer, and was heated to 80° C., and after replacing the inside of the reaction container with nitrogen, from the dropping tube, a mixture of 20 parts by mass of methacrylic acid, 20 parts by mass of para-cumylphenol ethyleneoxide-modified acrylate (ARONIX M110 manufactured by TOAGOSEI CO., LTD.), 45 parts by mass of methyl methacrylate, 8.5 parts by mass of 2-hydroxyethyl methacrylate, and 1.33 parts by mass of 2,2′-azobisisobutyronitrile was added dropwise thereto over 2 hours. After the dropwise addition, the reaction was continued for another 3 hours. Next, for the total amount of the obtained solution, nitrogen gas was stopped and dry air was injected for 1 hour, and the mixture was stirred and then cooled to room temperature. Thereafter, a mixture of 6.5 parts by mass of 2-methacryloyloxyethyl isocyanate (manufactured by SHOWA DENKO K.K., Karenz MOI), 0.08 parts by mass of dibutyltin laurate, and 26 parts by mass of cyclohexanone was added dropwise thereto at 70° C. over 3 hours. After the dropwise addition, the reaction was continued for another 1 hour to obtain a resin (Mw=18000). After cooling to room temperature, the reactant was diluted with PGMEA to adjust the concentration of solid contents to 20 mass %, thereby preparing the resin solution 11.

### EXPLANATION OF REFERENCES

1: green pixel
2: red pixel
5: partition wall

What is claimed is:

1. A color filter comprising:
a green pixel; and
a red pixel,
wherein the green pixel includes Color Index Pigment Green 7 and Color Index Pigment Yellow 150, and
the red pixel includes one or more red colorants selected from the group consisting of Color Index Pigment Red 177, Color Index Pigment Red 264, and Color Index Pigment Red 269, and a yellow colorant other than Color Index Pigment Yellow 150.

2. The color filter according to claim 1,
wherein a side surface of the green pixel and a side surface of the red pixel are in contact with each other.

3. The color filter according to claim 1,
wherein the yellow colorant other than Color Index Pigment Yellow 150, which is included in the red pixel, is at least one selected from the group consisting of an isoindoline compound and a quinophthalone compound.

4. The color filter according to claim 1,
wherein the yellow colorant other than Color Index Pigment Yellow 150, which is included in the red pixel, is at least one selected from the group consisting of Color Index Pigment Yellow 139 and Color Index Pigment Yellow 185.

5. The color filter according to claim 1,
wherein the green pixel includes 50 to 240 parts by mass of Color Index Pigment Yellow 150 with respect to 100 parts by mass of Color Index Pigment Green 7.

6. The color filter according to claim 1,
wherein the red pixel includes 5 to 100 parts by mass of the yellow colorant other than Color Index Pigment Yellow 150 with respect to 100 parts by mass of the one or more red colorants selected from the group consisting of Color Index Pigment Red 177, Color Index Pigment Red 264, and Color Index Pigment Red 269.

7. The color filter according to claim 1,
wherein, in light having a wavelength range of 400 to 700 nm, a difference between a wavelength of light on a short wavelength side where a transmittance of the green pixel is 5% and a wavelength of light on a long wavelength side where a transmittance of the red pixel is 5% is 98 to 115 nm.

8. The color filter according to claim 1,
wherein, in light having a wavelength range of 400 to 700 nm, a difference between a wavelength of light on a long wavelength side where a transmittance of the green pixel is 30% and a wavelength of light on a long wavelength side where a transmittance of the red pixel is 30% is 10 to 33 nm.

9. The color filter according to claim 1, further comprising:
a blue pixel.

10. A method for manufacturing the color filter according to claim 1, the method comprising:
forming a green pixel using a composition for a green pixel, which includes Color Index Pigment Green 7 and Color Index Pigment Yellow 150; and
forming a red pixel using a composition for a red pixel, which includes one or more red colorants selected from the group consisting of Color Index Pigment Red 177, Color Index Pigment Red 264, and Color Index Pigment Red 269, and a yellow colorant other than Color Index Pigment Yellow 150.

11. The method of manufacturing the color filter according to claim 10,
wherein, forming a green pixel, the green pixel is formed by a photolithography method using the composition for a green pixel, and
forming a red pixel, the red pixel is formed by a photolithography method using the composition for a red pixel.

12. The method for manufacturing the color filter according to claim 10,
wherein at least one selected from the composition for a green pixel or the composition for a red pixel includes an alkali-soluble resin.

13. The method for manufacturing the color filter according to claim 10,
wherein at least one selected from the composition for a green pixel or the composition for a red pixel includes a resin which has a repeating unit including a blocked isocyanate group.

14. The method for manufacturing the color filter according to claim 10,
wherein forming a green pixel and forming a red pixel are each performed at a temperature of 150° C. or lower.

15. A solid-state imaging element comprising:
the color filter according to claim 1.

16. A display device comprising:
the color filter according to claim 1.
